(19) United States
(12) Patent Application Publication
(10) Pub. No.: US 2026/0082691 A1
(43) Pub. Date: Mar. 19, 2026

(54) INTEGRATED CIRCUIT DEVICES

(71) Applicant: SAMSUNG ELECTRONICS CO., LTD., Suwon-si (KR)

(72) Inventors: Woohyeon CHOI, Suwon-si (KR); Kyunam PARK, Suwon-si (KR); Wooseok PARK, Suwon-si (KR); Changdeok SEO, Suwon-si (KR); Myungil KANG, Suwon-si (KR); Doyoung CHOI, Suwon-si (KR)

(73) Assignee: SAMSUNG ELECTRONICS CO., LTD., Suwon-si (KR)

(21) Appl. No.: 19/281,119

(22) Filed: Jul. 25, 2025

(30) Foreign Application Priority Data
Sep. 13, 2024 (KR) 10-2024-0126166

(51) Int. Cl. H10D 84/83; H01L 23/528; H10D 30/00; H10D 30/01; H10D 62/10; H10D 62/13; H10D 64/23; H10D 84/01

(52) U.S. Cl. CPC H10D 84/833; H10D 30/502; H10D 62/102; H10D 62/151; H10D 64/256; H10W 20/435; H10D 30/0191; H10D 84/0153

(57) ABSTRACT

An integrated circuit device may include at least one first semiconductor pattern extending in a first horizontal direction, a first source/drain region connected to an end of the at least one first semiconductor pattern in the first horizontal direction, at least one second semiconductor pattern extending in the first horizontal direction and spaced apart from the at least one first semiconductor pattern in a second horizontal direction, a second source/drain region connected to an end of the at least one second semiconductor pattern in the first horizontal direction, and an insulating wall in an insulating wall opening that extends in the first horizontal direction, between the at least one first semiconductor pattern and the at least one second semiconductor pattern and between the first source/drain region and the second source/drain region.

### CROSS-REFERENCE TO RELATED APPLICATION

This application is based on and claims priority under 35 U.S.C. § 119 to Korean Patent Application No. 10-2024-0126166, filed on Sep. 13, 2024, in the Korean Intellectual Property Office, the disclosure of which is incorporated by reference herein in its entirety.

### BACKGROUND

One or more embodiments of the present disclosure relate to an integrated circuit device, and more particularly, to an integrated circuit device including a field effect transistor.

As miniaturization, multi-functionality, and high performance of electronic products are required, high-capacity integrated circuit devices are required. To achieve high-capacity integrated circuit devices, increased integration is required. For example, in order to improve the performance of a device, it may be necessary to find a new method through a change in the structure of the device. As a result, an integrated circuit device including a transistor with a new structure may be needed.

### SUMMARY

One or more embodiments of the present disclosure provide an integrated circuit device having a transistor including a multi-gate metal oxide semiconductor field effect transistor (MOSFET) with improved operating characteristics.

According to an aspect of the disclosure, an integrated circuit device may include: at least one first semiconductor pattern extending in a first horizontal direction; a first source/drain region connected to an end of the at least one first semiconductor pattern in the first horizontal direction; at least one second semiconductor pattern extending in the first horizontal direction and spaced apart from the at least one first semiconductor pattern in a second horizontal direction; a second source/drain region connected to an end of the at least one second semiconductor pattern in the first horizontal direction; and an insulating wall in an insulating wall opening that extends in the first horizontal direction, between the at least one first semiconductor pattern and the at least one second semiconductor pattern and between the first source/drain region and the second source/drain region. The insulating wall may include: an insulating wall liner on an inner wall of the insulating wall opening; a buried insulating layer on the insulating wall liner; and an insulating wall capping layer on an upper surface of the insulating wall liner and an upper surface of the buried insulating layer in the insulating wall opening.

According to another aspect of the disclosure, an integrated circuit device may include: a first active region and a second active region extending in a first horizontal direction; an insulating wall extending in the first horizontal direction between the first active region and the second active region; at least one first semiconductor pattern on the first active region and extending in the first horizontal direction; a first source/drain region on the first active region and connected to the at least one first semiconductor pattern; at least one second semiconductor pattern that is on the second active region and extends in the first horizontal direction; and a second source/drain region on the second active region and connected to the at least one second semiconductor pattern. The insulating wall may include: a buried insulating layer extending in the first horizontal direction between the at least one first semiconductor pattern and the at least one second semiconductor pattern and between the first source/drain region and the second source/drain region; an insulating wall liner on sidewalls of the buried insulating layer; and an insulating wall capping layer on an upper surface of the insulating wall liner and an upper surface of the buried insulating layer.

According to another aspect of the disclosure, an integrated circuit device may include: a substrate including a first active region and a second active region; at least one first semiconductor pattern and at least one second semiconductor pattern provided on the first active region and the second active region, respectively; a first source/drain region and a second source/drain region that are on the first active region and the second active region, respectively, and are connected to the at least one first semiconductor pattern and the at least one second semiconductor pattern, respectively; and an insulating wall between the first active region and the second active region, and between the at least one first semiconductor pattern and the at least one second semiconductor pattern. The insulating wall may include: a buried insulating layer; an insulating wall liner on sidewalls of the buried insulating layer; and an insulating wall capping layer on an upper surface of the insulating wall liner and an upper surface of the buried insulating layer.

### BRIEF DESCRIPTION OF DRAWINGS

Embodiments will be more clearly understood from the following detailed description taken in conjunction with the accompanying drawings in which:

FIG. 1 is a schematic layout diagram of an integrated circuit device according to embodiments;

FIG. 2 is a perspective view showing a schematic configuration of the integrated circuit device of FIG. 1;

FIG. 3A is a cross-sectional view of the integrated circuit device taken along line A-A′ of FIG. 1;

FIG. 3B is a cross-sectional view of the integrated circuit device taken along line B-B′ of FIG. 1;

FIG. 3C is a cross-sectional view of the integrated circuit device taken along line C-C′ of FIG. 1;

FIG. 4A is an enlarged view of an area CX1 of FIG. 3B;

FIG. 4B is an enlarged view of an area CX2 of FIG. 3C;

FIGS. 5A, 5B, and 5C are cross-sectional views illustrating an integrated circuit device according to embodiments; and

FIGS. 6A, 6B, 6C, 7A, 7B, 7C, 8A, 8B, 9A, 9B, 10, 11, 12A, 12B, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, and 20C are cross-sectional views illustrating a method of manufacturing an integrated circuit device, according to embodiments.

### DETAILED DESCRIPTION

Hereinafter, embodiments of the technical idea of the inventive concept will be described in detail with reference to the attached drawings.

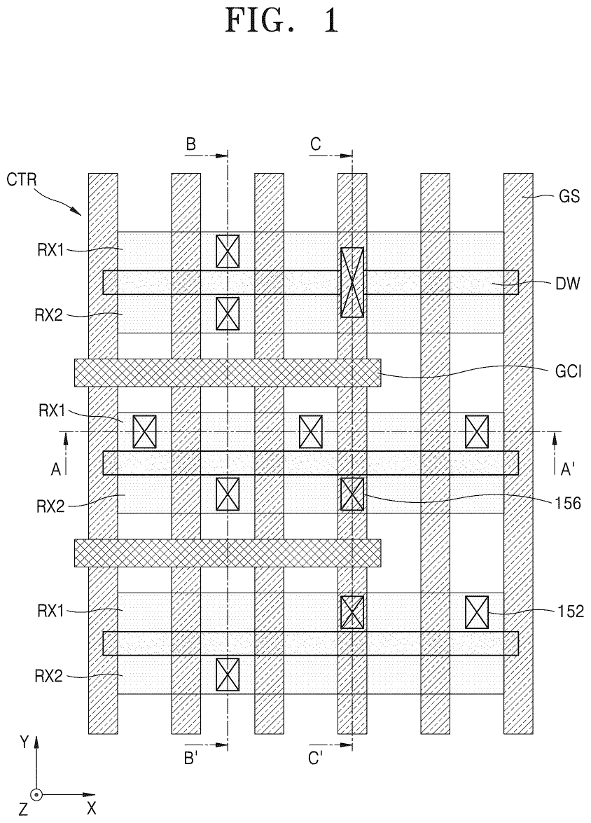

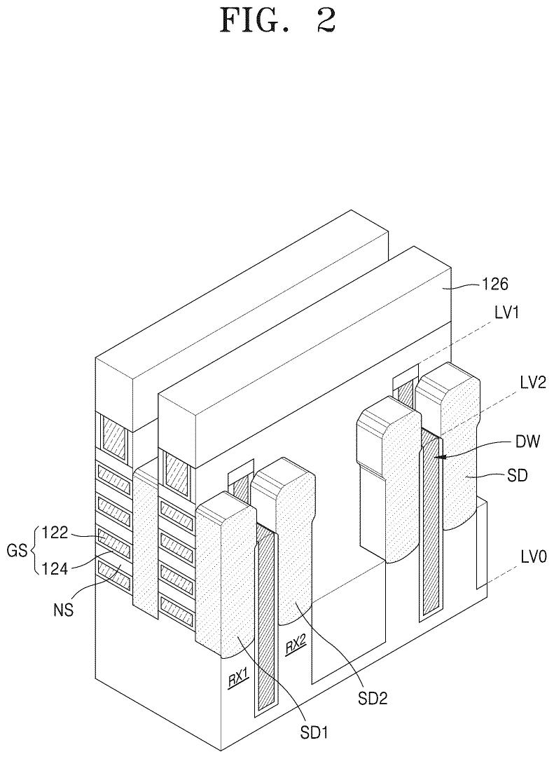

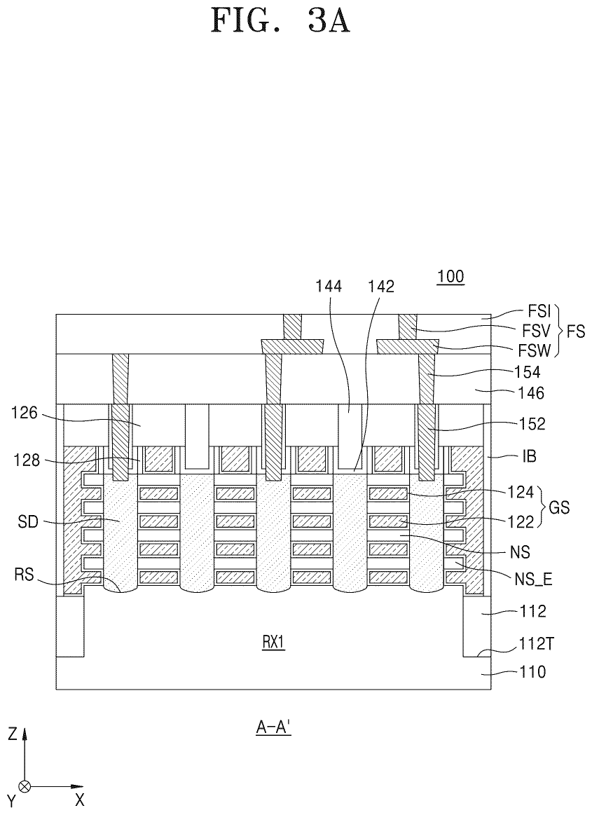

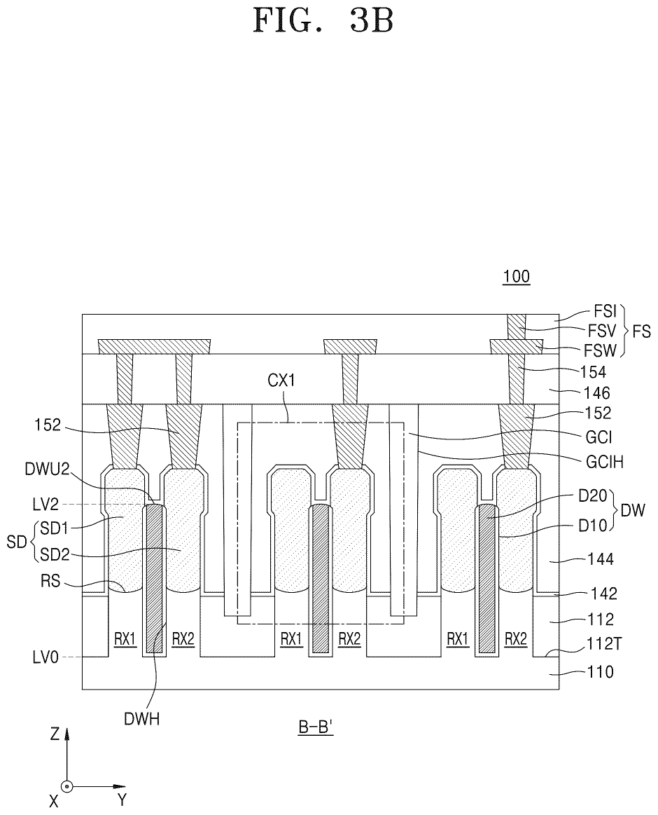

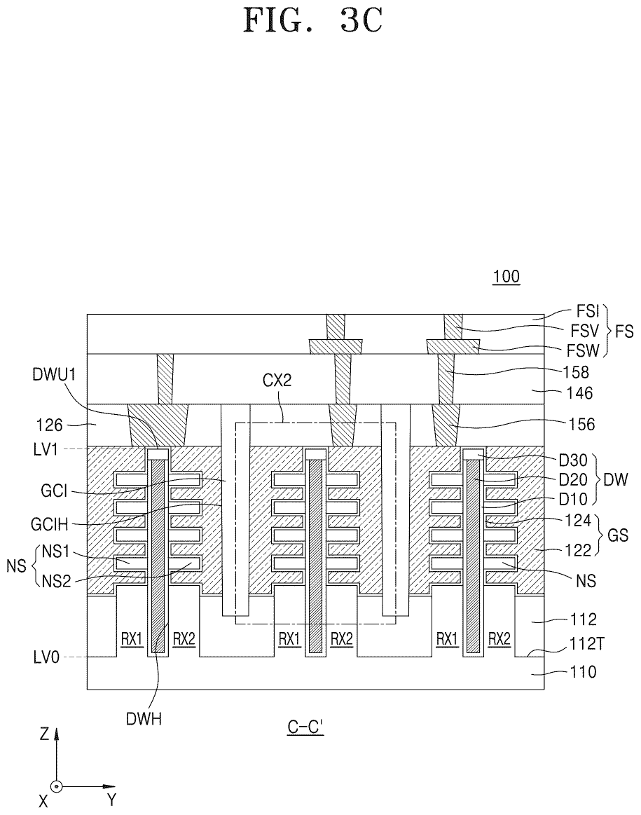

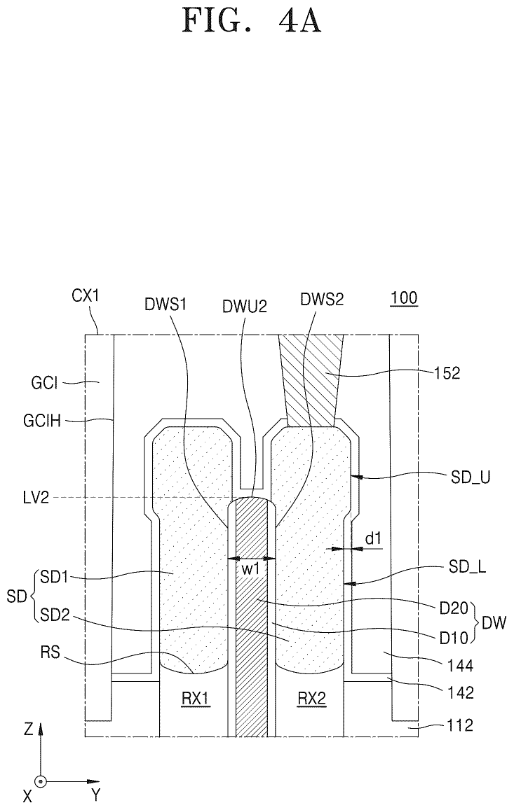

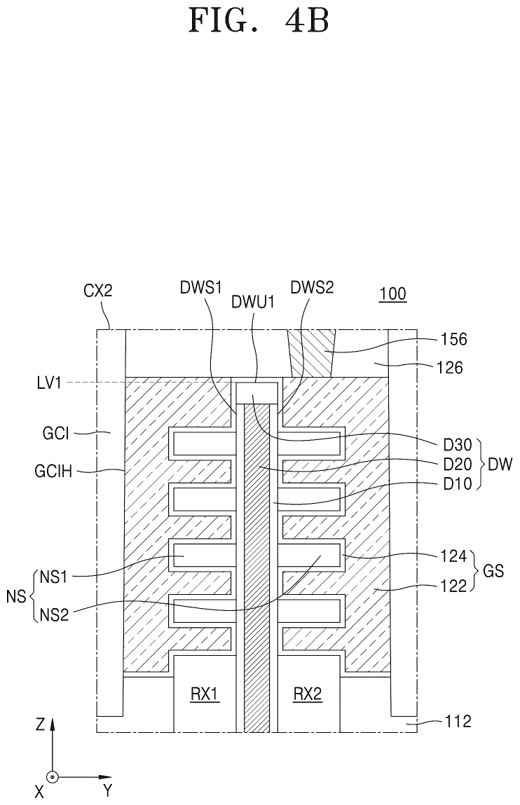

FIG. 1 is a schematic layout diagram of an integrated circuit device according to embodiments. FIG. 2 is a perspective view showing a schematic configuration of the integrated circuit device 100 of FIG. 1. FIG. 3A is a cross-sectional view of the integrated circuit device 100 taken along line A-A′ of FIG. 1. FIG. 3B is a cross-sectional view of the integrated circuit device 100 taken along line B-B′ of FIG. 1. FIG. 3C is a cross-sectional view of the integrated circuit device 100 taken along line C-C′ of FIG. 1. FIG. 4A is an enlarged view of an area CX1 of FIG. 3B. FIG. 4B is an enlarged view of an area CX2 of FIG. 3C.

Referring to FIGS. 1, 2, 3A, 3B, 3C, 4A, and 4B, the integrated circuit device 100 may include a plurality of cell transistors CTR arranged at a first vertical level, and a front wiring structure FS arranged at a second vertical level higher than the first vertical level and electrically connected to the plurality of cell transistors CTR.

The plurality of cell transistors CTR may configure various types of logic cells included in a logic circuit. In embodiments, the integrated circuit device 100 may configure a logic cell including a multi-bridge channel field-effect transistor (MBCFET) device.

The integrated circuit device 100 may include a first active region RX1 and a second active region RX2 that respectively protrude from an upper surface of a substrate 110 and extend in a first horizontal direction X. In embodiments, the first active region RX1 and the second active region RX2 may protrude in a vertical direction Z from the upper surface of the substrate 110 and extend in the first horizontal direction X. A device isolation layer 112 may be arranged within a device isolation trench 112T extending into the substrate 110, and at least portions of sidewalls of the first active region RX1 and the second active region RX2 may be in contact with the device isolation layer 112.

In embodiments, the first active region RX1 and the second active region RX2 may be p-channel metal oxide semiconductor (PMOS) transistor regions or n-channel metal oxide semiconductor (NMOS) transistor regions. In embodiments, the plurality of cell transistors CTR that are arranged on or within the first active region RX1 and the second active region RX2 may include PMOS transistors. In embodiments, the plurality of cell transistors CTR arranged within the first active region RX1 and the second active region RX2 may include NMOS transistors. In other embodiments, a plurality of cell transistors CTR arranged within the first active region RX1 may include PMOS transistors and a plurality of cell transistors CTR arranged within the second active region RX2 may include NMOS transistors.

In embodiments, an insulating wall DW extending in the first horizontal direction X may be arranged between the first active region RX1 and the second active region RX2. The insulating wall DW may be arranged within an insulating wall opening DWH extending into the substrate 110 between the first active region RX1 and the second active region RX2. The bottom surface of the insulating wall opening DWH may be arranged at a vertical level that is the same as a level LV0 of the bottom surface of the device isolation trench 112T.

The insulating wall DW may include an insulating wall liner D10 arranged on an inner wall of the insulating wall opening DWH, a buried insulating layer D20 that fills the insulating wall opening DWH on the insulating wall liner D10, and an insulating wall capping layer D30 arranged on the buried insulating layer D20 and the insulating wall liner D10.

In embodiments, the insulating wall liner D10 may include a low-k dielectric layer (e.g., a dielectric constant in the range of 2.0 to 3.0). For example, the insulating wall liner D10 may include at least one of silicon carbon oxide, silicon carbon nitride, or silicon carbon oxynitride. In embodiments, the buried insulating layer D20 may include at least one of silicon nitride, silicon oxide, or silicon oxynitride. In embodiments, the insulating wall capping layer D30 may include at least one of silicon nitride, silicon oxide, or silicon oxynitride.

In embodiments, the insulating wall DW may include a first portion DWU1 and a second portion DWU2 that have different heights in the vertical direction Z. For example, the first portion DWU1 of the insulating wall DW may have an upper surface arranged at a first vertical level LV1, and the second portion DWU2 of the insulating wall DW may have an upper surface arranged at a second vertical level LV2 lower than the first vertical level LV1. For example, with respect to the level LV0 of the bottom surface of the device isolation trench 112T, the second vertical level LV2 may be lower than the first vertical level LV1.

In embodiments, an upper portion of the insulating wall DW may be removed through a recess process, which lowers an upper surface level of the second portion DWU2 of the insulating wall DW. In the recess process, a portion of the insulating wall capping layer D30 within the second portion DWU2 of the insulating wall DW may be removed, leaving the insulating wall capping layer D30 only in the first portion DWU1 of the insulating wall DW, As a result, the capping layer D30 may be absent in the second portion DWU2 of the insulating wall DW. For example, the upper surface of the insulating wall capping layer D30 within the first portion DWU1 of the insulating wall DW may be positioned at the first vertical level LV1, while the upper surface of the second portion DWU2 of the insulating wall DW may be arranged at the second vertical level LV2.

A plurality of cell transistors CTR may be arranged on the first active region RX1 and the second active region RX2, and may be arranged apart from each other in the first horizontal direction X and a second horizontal direction Y. The plurality of cell transistors CTR may include a plurality of semiconductor patterns NS arranged apart from each other in the vertical direction Z, a plurality of gate structures GS surrounding the plurality of semiconductor patterns NS and extending in the second horizontal direction Y, and a plurality of source/drain regions SD arranged on both sides of the plurality of gate structures GS.

In embodiments, each of the plurality of semiconductor patterns NS may include a group IV semiconductor such as Si or Ge, a group IV-IV compound semiconductor such as SiGe or SiC, or a group III-V compound semiconductor such as GaAs, InAs, or InP.

In embodiments, each of the plurality of semiconductor patterns NS may be arranged on a sidewall of the insulating wall DW and may be apart from each other in the vertical direction X on the sidewall of the insulating wall DW. In embodiments, a plurality of semiconductor patterns NS arranged on the first active region RX1 (or at a position vertically overlapping the first active region RX1) (herein, each of the plurality of semiconductor patterns NS arranged on the first active region RX1 is referred to as a first semiconductor pattern NS1) may be arranged on a first sidewall DWS1 of the insulating wall DW and be in contact with the first sidewall DWS1. In embodiments, a plurality of semiconductor patterns NS arranged on the second active region RX2 (or at a position vertically overlapping the second active region RX2) (herein, each of the plurality of semiconductor patterns NS arranged on the second active region RX2 is referred to as a second semiconductor pattern NS2) may be arranged on a second sidewall DWS2 of the insulating wall DW opposite to the first sidewall DWS1 of the insulating wall DW and be in contact with the second sidewall DWS2.

In embodiments, an end of the first semiconductor pattern NS1 in the second horizontal direction Y may be in contact with the first sidewall DWS1 of the insulating wall DW, and an end of the second semiconductor pattern NS2 in the second horizontal direction Y may be in contact with the second sidewall DWS2 of the insulating wall DW. In embodiments, the first semiconductor pattern NS1 and the second semiconductor pattern NS2 may be arranged to be apart from each other in the second horizontal direction Y with the insulating wall DW therebetween and may be in contact with a sidewall of the insulating wall liner D10.

In embodiments, the upper surface of the insulating wall liner D10 included in the first portion DWU1 of the insulating wall DW may be arranged at a vertical level higher than the upper surface of the uppermost semiconductor pattern NS among the plurality of semiconductor patterns NS. The upper surface of the insulating wall liner D10 included in the first portion DWU1 of the insulating wall DW may be arranged at a vertical level lower than the upper surface of the insulating wall capping layer D30 included in the first portion DWU1 of the insulating wall DW. Accordingly, the insulating wall liner D10 may not be exposed to an etching atmosphere in an insulating layer forming process for forming the device isolation layer 112 and/or a subsequent etch-back process.

In embodiments, the plurality of gate structures GS may extend in the second horizontal direction Y to surround the plurality of semiconductor patterns NS on the first sidewall DWS1 and the second sidewall DWS2 of the insulating wall DW and may be arranged apart from each other in the first horizontal direction X.

In embodiments, each of the plurality of gate structures GS may include a gate electrode 122 and a gate insulating layer 124. For example, the gate electrode 122 may extend in the second horizontal direction Y to surround the plurality of semiconductor patterns NS, and the gate insulating layer 124 may be arranged between the gate electrode 122 and each of the semiconductor patterns NS.

In embodiments, the gate insulating layer 124 may be arranged on the upper surfaces, sidewalls, and bottom surfaces of the plurality of semiconductor patterns NS and may conformally extend onto the first sidewall DWS1 and the second sidewall DWS2 of the insulating wall DW. In some embodiments, a portion of the gate insulating layer 124 may be arranged on the upper surface of the first portion DWU1 of the insulating wall DW (e.g., the upper surface of the insulating wall capping layer D30). Another portion of the gate insulating layer 124 may be arranged on the upper surface of the first active region RX1, the upper surface of the second active region RX2, and the upper surface of the device isolation layer 112.

In embodiments, the gate electrode 122 may include doped polysilicon, a metal, a conductive metal nitride, a conductive metal carbide, a conductive metal silicide, or a combination thereof. For example, the gate electrode 122 may include, but is not limited to, Al, Cu, Ti, Ta, W, Mo, TaN, NiSi, CoSi, TiN, WN, TiAl, TiAlN, TaCN, TaC, TaSiN, or a combination thereof. In embodiments, the gate electrode 122 may include a work function metal-containing layer and a gap fill metal layer. The work function metal-containing layer may include at least one metal selected from Ti, W, Ru, Nb, Mo, Hf, Ni, Co, Pt, Yb, Tb, Dy, Er, and Pd. The gap fill metal layer may include a W layer or an Al layer. In embodiments, the gate electrode 122 may include, but is not limited to, a stacked structure of TiAlC/TiN/W layers, a stacked structure of TiN/TaN/TiAlC/TiN/W layers, or a stacked structure of TiN/TaN/TiN/TiAlC/TiN/W layers.

In embodiments, the gate insulating layer 124 may include a silicon oxide layer, a silicon oxynitride layer, a high-k dielectric layer having a higher dielectric constant than the silicon oxide layer, or a combination thereof. The high-k dielectric layer may include a metal oxide or a metal oxynitride. For example, a high-k dielectric layer usable as the gate insulating layer 124 may include, but is not limited to, HfO₂, HfSiO, HfSiON, HfTaO, HfTiO, HfZrO, ZrO₂, Al₂O₃, or a combination thereof.

In embodiments, a capping layer 126 may extend in the second horizontal direction Y on the upper surface of the gate electrode 122. In embodiments, the capping layer 126 may include silicon oxide (SiOₓ), silicon nitride (SiNₓ), silicon oxynitride (SiOₓN_{y}), silicon carbon nitride (SiCₓN_{y}), silicon carbon nitride (SiOₓC_{y}N_{z}), or a combination thereof.

In embodiments, a spacer 128 may be further arranged on both sidewalls of a portion of the gate structure GS arranged at a higher level than the uppermost semiconductor pattern NS The spacer 128 may extend in the second horizontal direction Y on both sidewalls of the gate electrode 122 arranged at a level higher than the uppermost semiconductor pattern NS (or on sidewalls of the gate insulating layer 124 arranged at a level than higher the uppermost semiconductor pattern NS), and the capping layer 126 may be arranged on the upper surface of the spacer 128. In some other embodiments, the spacer 128 may extend onto both sidewalls of the capping layer 126 and both sidewalls of the gate electrode 122.

In embodiments, the upper surface of the gate structure GS may be arranged at a vertical level higher than the bottom surface of the insulating wall capping layer D30 of the insulating wall DW. The upper surface of the first portion DWU1 of the insulating wall DW surrounded by the gate electrode 122 may be arranged at a first vertical level LV1, and the upper surface of the first portion DWU1 of the insulating wall DW may have a substantially flat profile.

A source/drain region SD may be formed on both sides of the gate structure GS. The source/drain region SD may be arranged on a recess RS formed in the first active region RX1 and the second active region RX2 and may be connected to both ends of a plurality of semiconductor patterns NS. The source/drain region SD may have an upper surface arranged at a level that is the same as or higher than the level of the upper surface of the uppermost semiconductor pattern NS.

In embodiments, the source/drain region SD may include, but is not limited to, a doped SiGe layer, a doped Ge layer, a doped SiC layer, or a doped InGaAs layer. In embodiments, the source/drain region SD may include a plurality of semiconductor layers having different compositions. For example, the source/drain region SD may include a lower semiconductor layer, an upper semiconductor layer, and a capping semiconductor layer that are sequentially stacked. For example, the lower semiconductor layer, the upper semiconductor layer, and the capping semiconductor layer may each include SiC and have different contents of Si and C

In embodiments, the second portion DWU2 of the insulating wall DW may be arranged between a source/drain region SD (herein, referred to as a first source/drain region SD1) arranged on the first active region RX1 and a source/drain region SD (herein, referred to as a second source/drain region SD2) arranged on the second active region RX2.

In embodiments, a portion of the second portion DWU2 of the insulating wall DW arranged between the first source/drain region SD1 and the second source/drain region SD2 may be removed by a recess process, and thus, the second portion DWU2 may include a round upper surface.

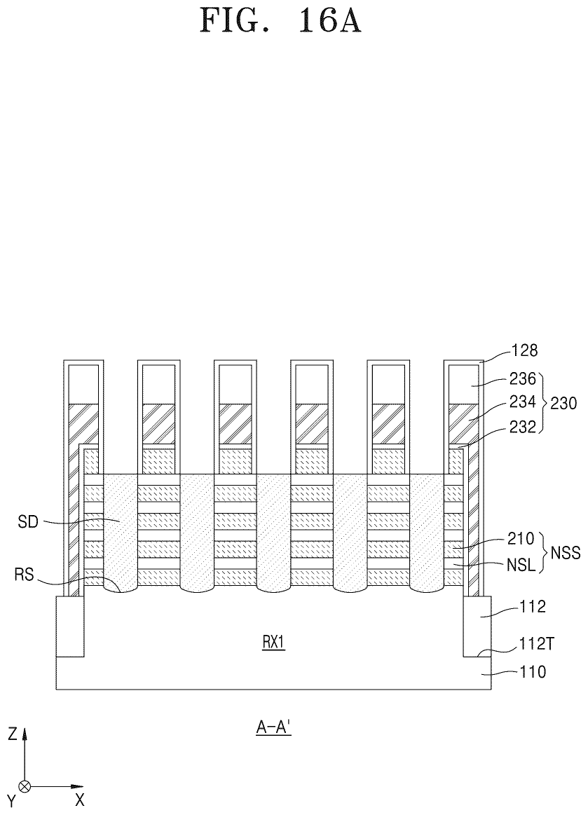

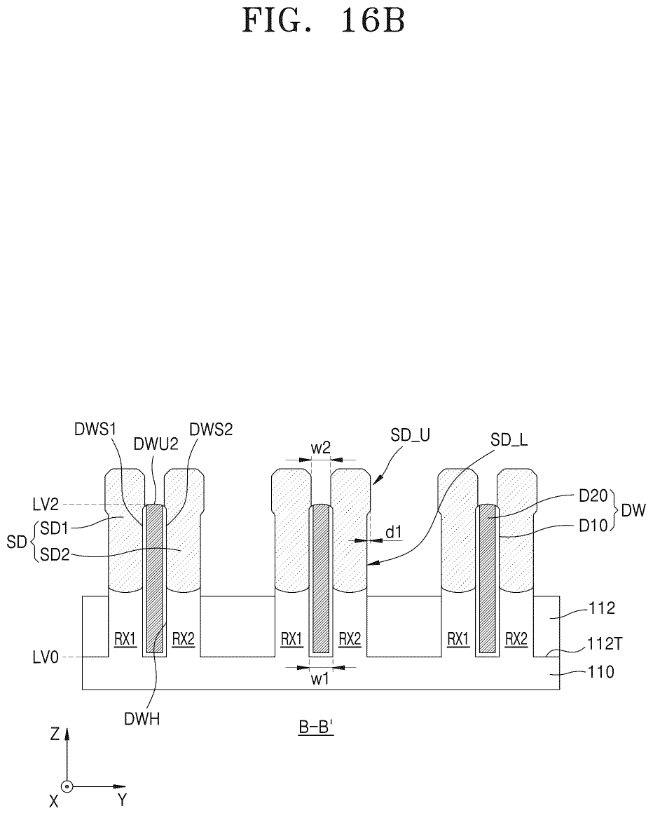

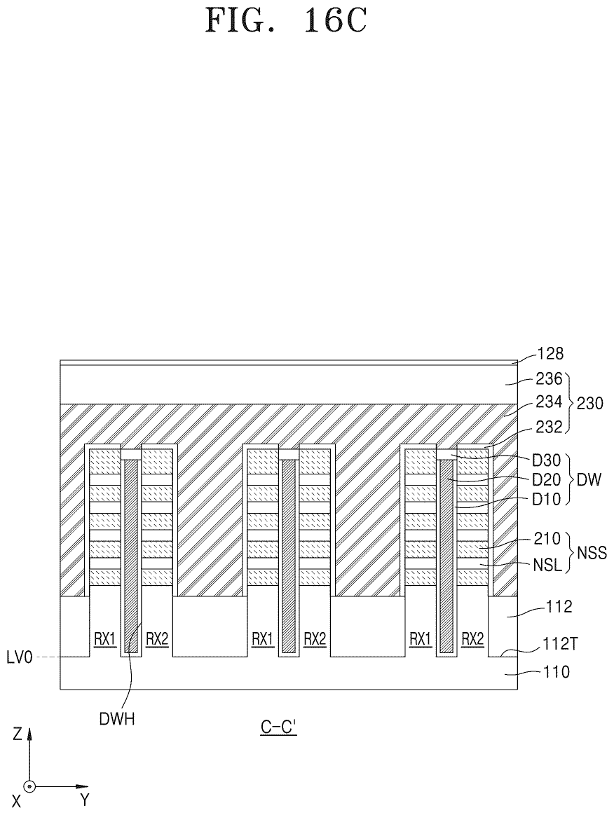

In embodiments, the first source/drain region SD1 and the second source/drain region SD2 may have upper surfaces located at a higher vertical level than the upper surface of the second portion DWU2 of the insulating wall DW arranged therebetween. In addition, upper portions of the first source/drain region SD1 and the second source/drain region SD2 may be arranged apart from each other by a relatively small separation distance w2 (see FIG. 16B) at a higher vertical level than the upper surface of the second portion DWU2 of the insulating wall DW.

In embodiments, the source/drain region SD may include a lower sidewall SD_L in contact with the second portion DWU2 of the insulating wall DW, and an upper sidewall SD_U that is arranged at a vertical level higher than the lower sidewall SD_L and not in contact the second portion DWU2 of the insulating wall DW. In some embodiments, as illustrated in FIG. 4A, the upper sidewall SD_U of the source/drain region SD may protrude outwardly with respect to the lower sidewall SD_L of the source/drain region SD. For example, the upper sidewall SD_U of the source/drain region SD may be apart from the lower sidewall SD_L of the source/drain region SD by a first distance d1 in the second horizontal direction Y. In embodiments, the first distance d1 may be in a range of about 0.1 nanometers to about 5 nanometers.

In some embodiments, the insulating wall DW may have a first width w1 in the second horizontal direction Y, and the first width w1 may be in a range of about 15 nanometers to about 25 nanometers. Therefore, the first source/drain region SD1 and the second source/drain region SD2 may be apart from each other with the insulating wall DW therebetween.

The cell transistor CTR may be an NMOS transistor or a PMOS transistor depending on the conductivity type of the semiconductor pattern NS and/or the conductivity type of the source/drain region SD.

An etch stop layer 142 covering the upper surface of the source/drain region SD may be arranged between the gate structures GS, and an inter-gate insulating layer 144 filling a space between the gate structures GS may be formed on the etch stop layer 142. The etch stop layer 142 may include silicon oxide or silicon oxynitride, and the inter-gate insulating layer 144 may include silicon oxide or silicon oxynitride. The etch stop layer 142 may also be conformally arranged on the upper surface of the second portion DWU2 of the insulating wall DW arranged between the first source/drain region SD1 and the second source/drain region SD2.

A gate cut insulating layer GCI may be arranged on a sidewall of the gate structure GS in the second horizontal direction Y. The gate cut insulating layer GCI may fill the inside of a gate cut region GCIH formed by removing portions of the gate structure GS, the etch stop layer 142, and the inter-gate insulating layer 144. In embodiments, the bottom of the gate cut insulating layer GCI may extend to a level that is lower than the level of the bottom surface of the gate electrode 122 and may have a shape tapered downward. A bottom portion of the gate cut insulating layer GCI may be surrounded by the device isolation layer 112. The upper surface of the gate cut insulating layer GCI may be arranged coplanar with the upper surface of the capping layer 126.

An upper insulating layer 146 may be arranged on the gate cut insulating layer GCI and the inter-gate insulating layer 144. The upper insulating layer 146 may include silicon oxide or silicon oxynitride.

A first contact 152 and a first via 154 may be arranged on the source/drain region SD through the upper insulating layer 146 and the gate inter-insulating layer 144, and a second contact 156 and a second via 158 may be arranged on the gate electrode 122 through the upper insulating layer 146 and the capping layer 126. In embodiments, the first contact 152 and the first via 154 may be formed in a stack structure such that the first contact 152 is electrically connected to the source/drain region SD and the first via 154 is arranged on the first contact 152, and the second contact 156 and the second via 158 may be formed in a stack structure such that the second contact 156 is electrically connected to the gate electrode 122 and the second via 158 is arranged on the second contact 156. In other embodiments, the second via 158 may be omitted and the upper surface of the first via 154 may be arranged coplanar with the upper surface of the second contact 156 and the upper surface of the upper insulating layer 146. In other embodiments, the first via 154 and the second via 158 may be omitted, the first contact 152 may pass through the upper insulating layer 146, and the upper surface of the first contact 152 may be arranged coplanar with the upper surface of the second contact 156 and the upper surface of the upper insulating layer 146.

The front wiring structure FS electrically connected to the cell transistor CTR may be arranged on the upper insulating layer 146. The front wiring structure FS may include a front via FSV, a front wiring layer FSW, and a front insulating layer FSI. In embodiments, the front wiring layer FSW may be a wiring pattern arranged at one vertical level, or may be wiring patterns arranged at two or more vertical levels.

In embodiments, the front insulating layer FSI may include an oxide layer, a nitride layer, a low-k dielectric layer having a dielectric constant of about 2.2 to about 2.4, or a combination thereof. The front wiring layer FSW may be electrically connected to the first via 154 and the second via 158. The front via FSV may be electrically connected to the front wiring layer FSW, and the sidewalls of the front wiring layer FSW and the front via FSV may be surrounded by the front insulating layer FSI.

As integrated circuit devices continue to scale down, integrated circuit devices in which semiconductor patterns are arranged with an insulating wall therebetween have been proposed. When the insulating wall is formed first and then the semiconductor patterns are subsequently formed, residues from the semiconductor patterns may not be completely removed, potentially deteriorating device performance. To solve this, a method has been proposed where an insulating wall is formed between the semiconductor patterns after forming the semiconductor patterns first are crated. However, this approach may lead to increased width deviations in the semiconductor patterns, which may negatively affect device performances.

However, in the integrated circuit device 100 according to embodiments, the insulating wall DW including the insulating wall liner D10, the buried insulating layer D20, and the insulating wall capping layer D30, is first formed. A recess process is then performed on the upper portion of the insulating wall DW to reduce the height of the insulating wall DW, followed by the growth of the source/drain region SD. The insulating wall liner D10 may include a low-k dielectric material, which helps prevent coupling effects and improve threshold voltage control characteristics of the integrated circuit device 100. In addition, the insulating wall capping layer D30 may cover the upper surface of the insulating wall liner D10, protecting the insulating wall DW from potential loss or damage that may occur when the upper surface of the insulating wall liner D10 is exposed during the formation of the device isolation layer 112. As a result, the integrated circuit device 100 may have excellent electrical performance. The structure and material of the insulating wall DW in the integrated circuit device 100 may eliminate the need for a second wall, as relying on the single insulating wall DW alone may resolve the previous technical challenges associated with wall formation.

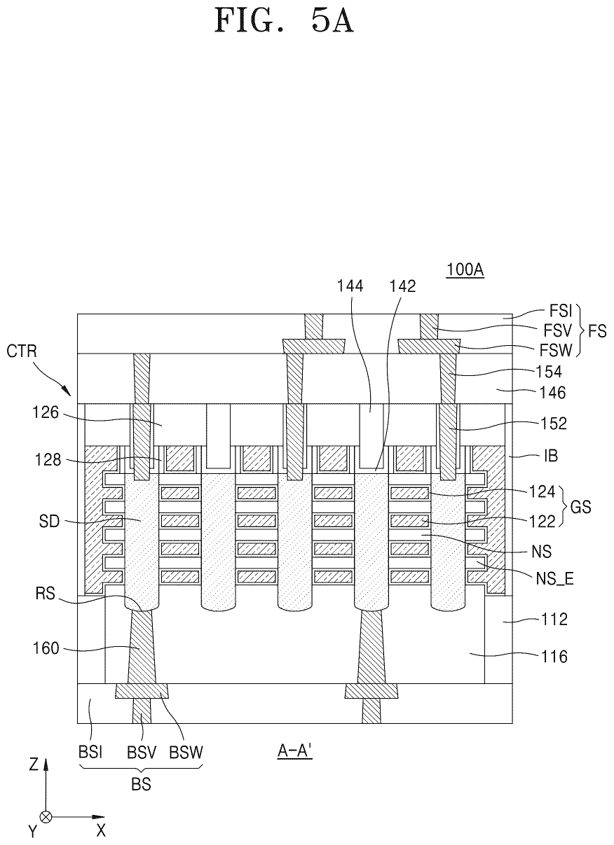

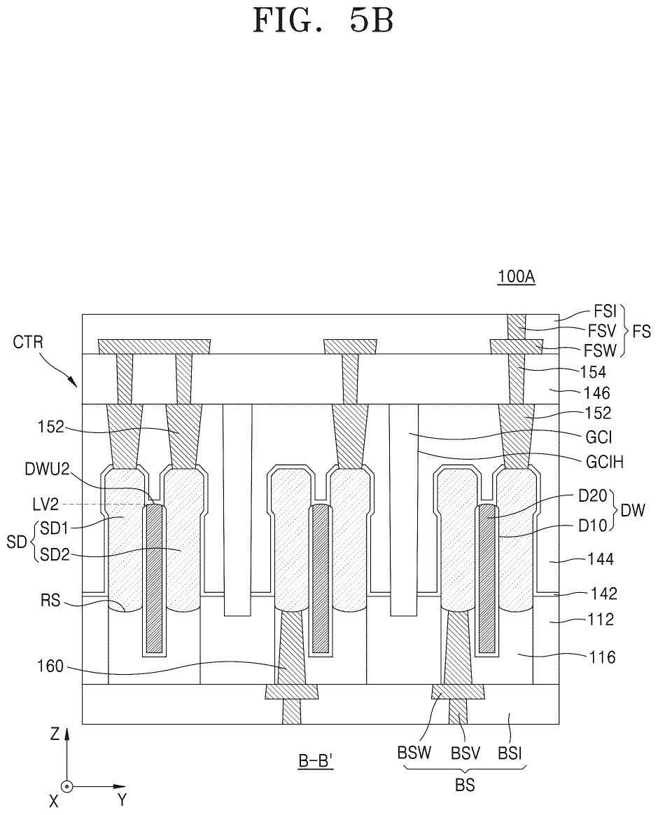

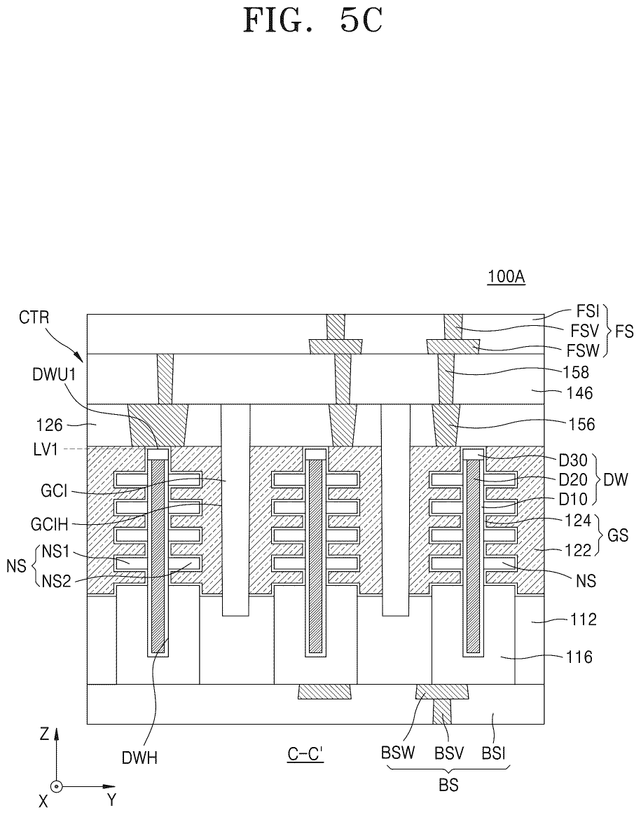

FIGS. 5A, 5B, and 5C are cross-sectional views illustrating an integrated circuit device 100A according to embodiments.

Referring to FIGS. 5A, 5B, and 5C, the integrated circuit device 100A may include a plurality of cell transistors CTR arranged at a first vertical level, a front wiring structure FS arranged at a second vertical level higher than the first vertical level and electrically connected to the plurality of cell transistors CTR, and a back wiring structure BS arranged at a third vertical level lower than the first vertical level and electrically connected to the plurality of cell transistors CTR.

The back wiring structure BS may include a power delivery network for applying a power voltage and a ground voltage to the cell transistors CTR. The back wiring structure BS may include a back via BSV, a back wiring layer BSW, and a back insulating layer BSI.

In the integrated circuit device 100A, a substrate 110 (see FIG. 3A) may be removed, and a base insulating layer 116 may be arranged at a location where the substrate 110 is removed. A back contact 160 may be arranged to pass through the base insulating layer 116 and be electrically connected to the bottom surface of the source/drain region SD. The back wiring structure BS may be arranged on the bottom surfaces of the base insulating layer 116 and the device isolation layer 112, and the back via BSV or the back wiring layer BSW may be arranged to be electrically connected to the back contact 160.

In some embodiments, a place holder may be further arranged between the bottom surface of the source/drain region SD and the back contact 160. However, the technical idea of the inventive concept is not limited thereto.

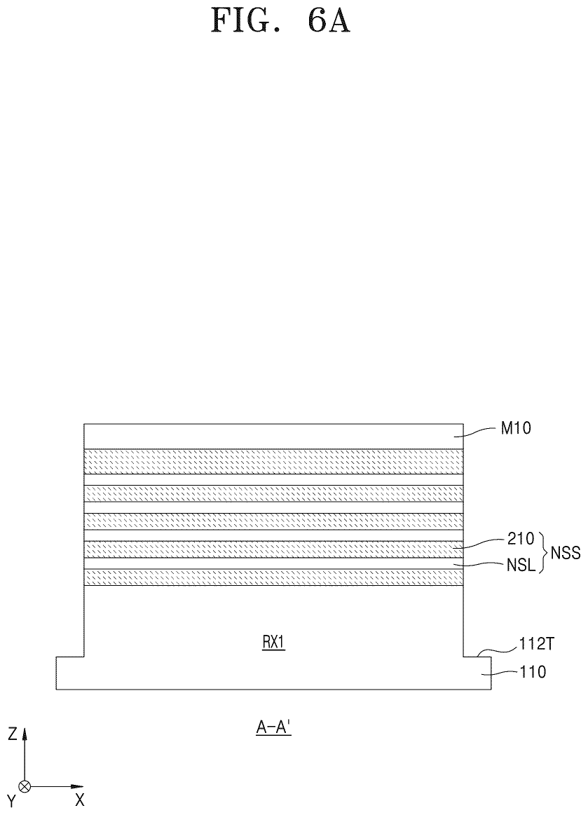

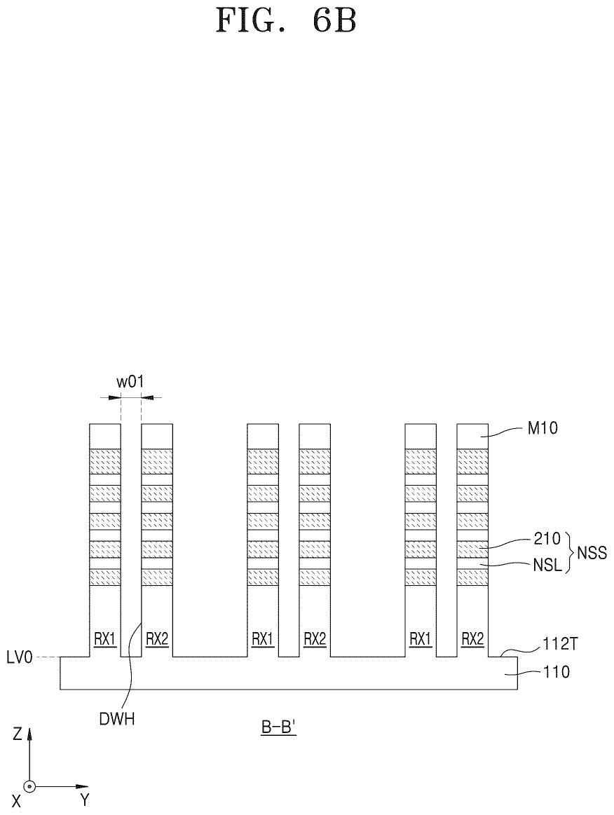

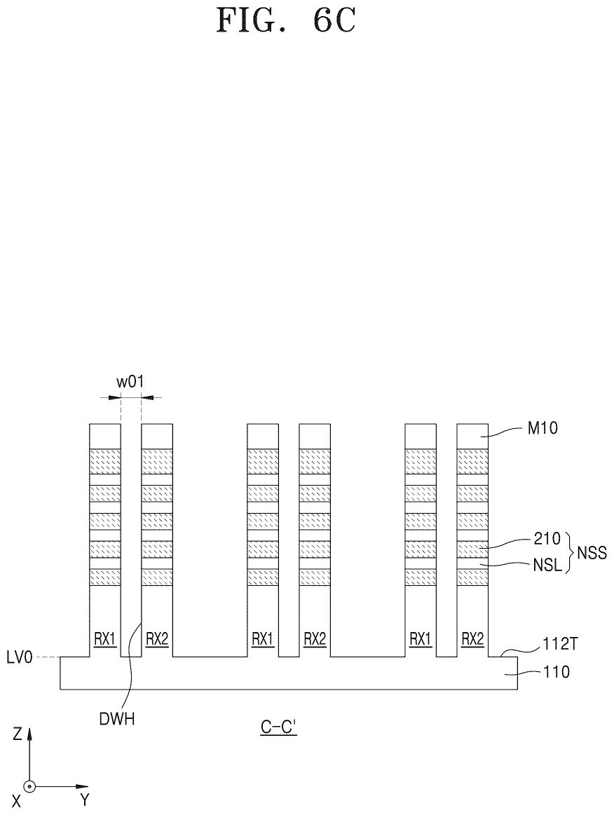

FIGS. 6A to 20C are cross-sectional views illustrating a method of manufacturing the integrated circuit device 100, according to embodiments.

Specifically, FIGS. 6A, 7A, 9A, 12A, 13A, 14A, 15A, 16A, 17A, 18A, 19A, and 20A are cross-sectional views corresponding to a cross-section taken along line A-A′ of FIG. 1, FIGS. 6B, 7B, 8A, 9B, 10, 11, 12B, 13B, 14B, 15B, 16B, 17B, 18B, 19B, and 20B are cross-sectional views corresponding to a cross-section taken along line B-B′ of FIG. 1, and FIGS. 6C, 7C, 8B, 13C, 14C, 15C, 16C, 17C, 18C, 19C, and 20C are cross-sectional views corresponding to a cross-section taken along line C-C′ of FIG. 1.

Referring to FIGS. 6A to 6C, a sacrificial layer 210 and a semiconductor layer NSL may be alternately and sequentially formed on the upper surface of a substrate 110 to form a semiconductor layer stack NSS. Thereafter, a mask pattern M10 may be formed on the semiconductor layer stack NSS, and a portion of the semiconductor layer stack NSS and a portion of the substrate 110 may be removed to form a device isolation trench 112T and an insulating wall opening DWH extending into the substrate 110.

In embodiments, the device isolation trench 112T and the insulating wall opening DWH may be alternately arranged and may extend in the first horizontal direction X.

In embodiments, the insulating wall opening DWH may have a first width w01 in the range of about 15 nanometers to about 25 nanometers in the second horizontal direction Y. A portion of the substrate 110 arranged on the first side of the insulating wall opening DWH is referred to as a first active region RX1, and a portion of the substrate 110 arranged on the second side of the insulating wall opening DWH is referred to as a second active region RX2. Accordingly, the first active region RX1 and the second active region RX2 may be arranged to extend in the first horizontal direction X with the insulating wall opening DWH therebetween.

In embodiments, the sacrificial layer 210 and the semiconductor layer NSL may be formed by an epitaxial growth process. In embodiments, the sacrificial layer 210 and the semiconductor layer NSL may include a material having an etching selectivity with respect to each other. For example, the sacrificial layer 210 and the semiconductor layer NSL may each include a single crystal layer of a group IV semiconductor, a group IV-IV compound semiconductor, or a group III-V compound semiconductor. The sacrificial layer 210 and the semiconductor layer NSL may include different materials. For example, the sacrificial layer 210 may include SiGe, and the semiconductor layer NSL may include single crystal silicon.

In embodiments, the epitaxy process may be a vapor-phase epitaxy (VPE), a chemical vapor deposition (CVD) process such as an ultra-high vacuum chemical vapor deposition (UHV-CVD), a molecular beam epitaxy, or a combination thereof. In the epitaxy process, a liquid or vapor phase precursor may be used as a precursor required for forming the sacrificial layer 210 and the semiconductor layer NSL.

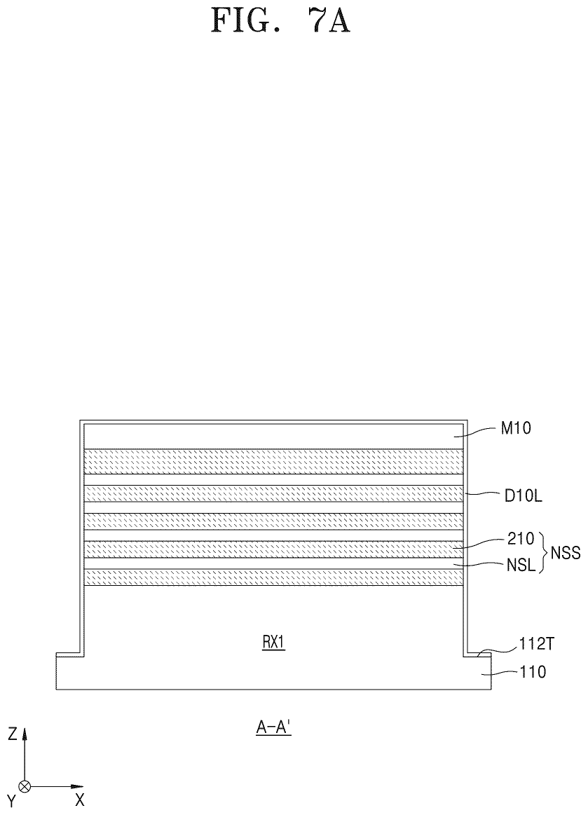

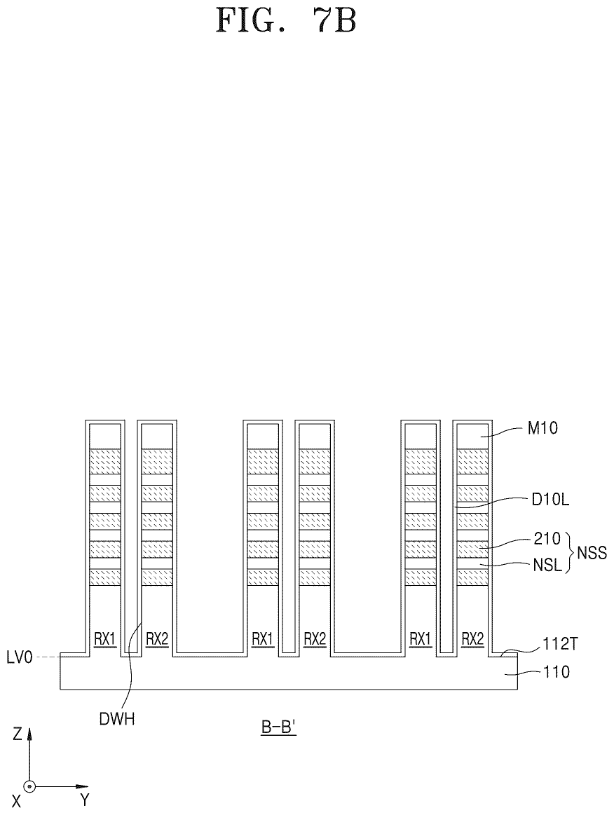

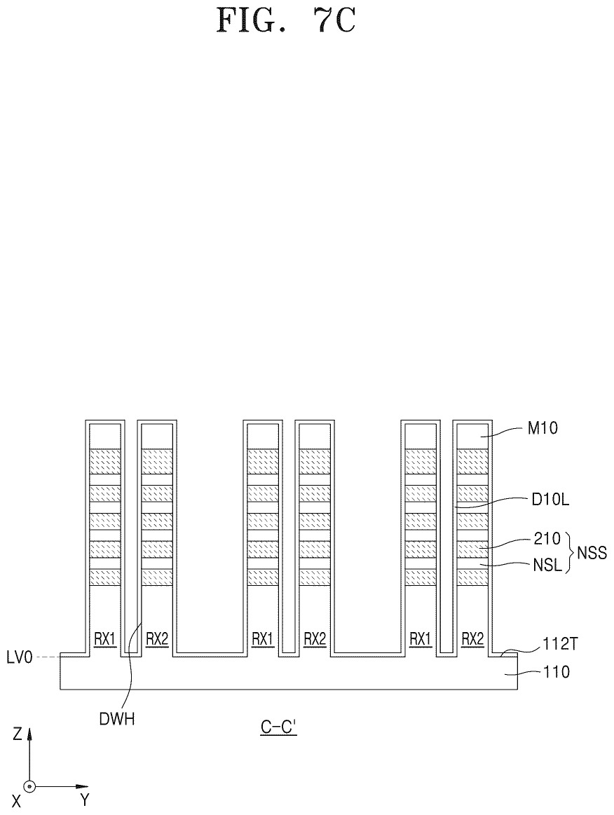

Referring to FIGS. 7A to 7C, an insulating wall liner layer D10L may be formed on the inner walls of the device isolation trench 112T and the insulating wall opening DWH. The insulating wall liner layer D10L may have a relatively small thickness and may be conformally arranged on the surface of the semiconductor layer stack NSS.

In embodiments, the insulating wall liner layer D10L may be formed by a CVD process or an atomic layer deposition (ALD) process by using a low-k dielectric material. For example, the insulating wall liner layer D10L may be formed using at least one of silicon carbon oxide, silicon carbon nitride, or silicon carbon oxynitride.

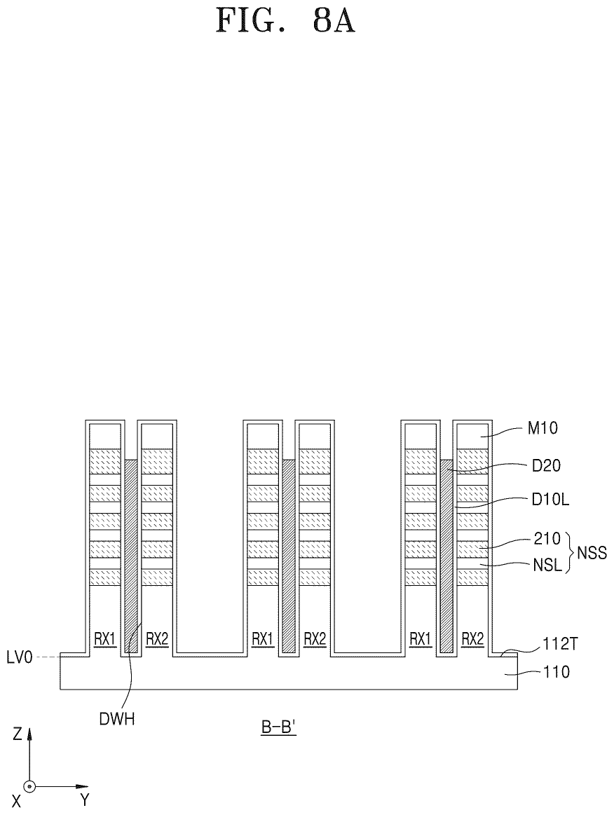

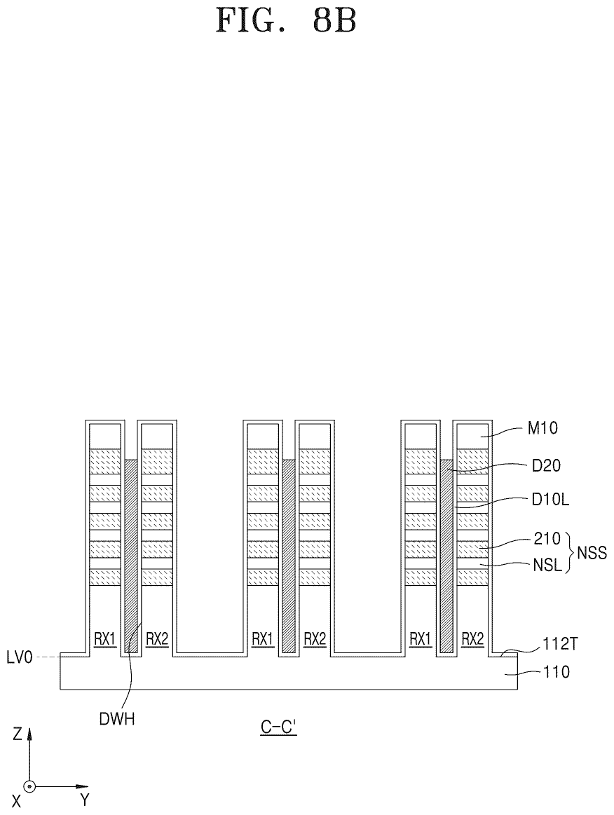

Referring to FIGS. 8A and 8B, a buried insulating layer D20 may be formed on an inner wall of the insulating wall opening DWH.

In embodiments, the buried insulating layer D20 may be formed on the insulating wall liner layer D10L to fill the interior of the insulating wall opening DWH. An etch-back process may be performed on the upper portion of the buried insulating layer D20, and thus, the upper surface of the buried insulating layer D20 may be arranged at a level lower than the upper surface of the semiconductor layer stack NSS.

In embodiments, the buried insulating layer D20 may be formed by a CVD process or an ALD process using at least one of silicon nitride, silicon oxide, or silicon oxynitride.

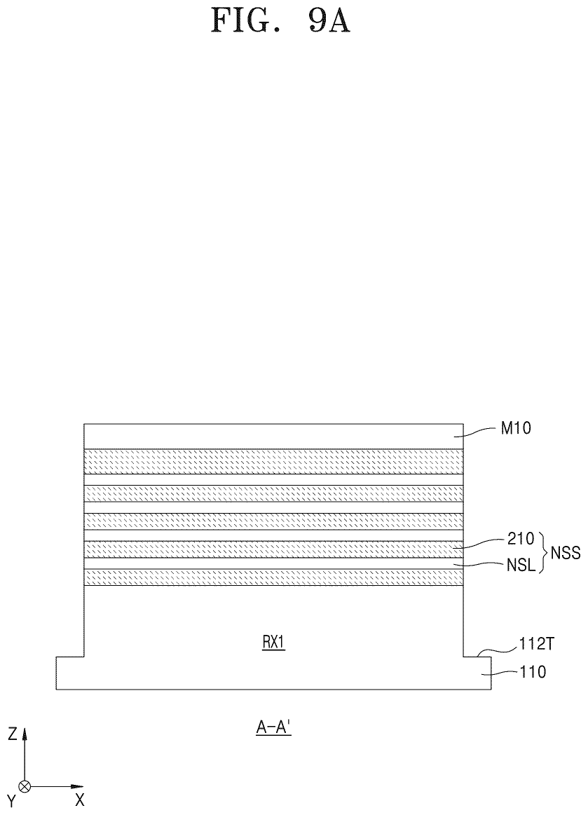

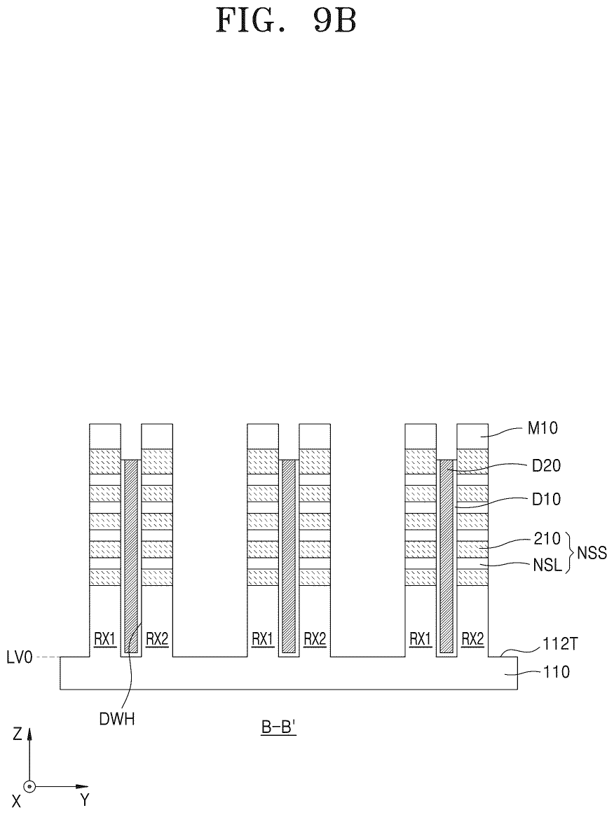

Referring to FIGS. 9A and 9B, an etch-back process may be performed so that the upper surface of the buried insulating layer D20 is exposed, thereby leaving a portion of the insulating wall liner layer D10L inside the insulating wall opening DWH and re-exposing the surface of the semiconductor layer stack NSS.

A portion of the insulating wall liner layer D10L remaining inside the insulating wall opening DWH may be referred to as an insulating wall liner D10.

The insulating wall liner D10 may have an upper surface that is arranged coplanar with the upper surface of the buried insulating layer D20. After the etch-back process, the upper surface of the insulating wall liner D10 and the upper surface of the buried insulating layer D20 may be arranged at a level that is higher than the level of the upper surface of the uppermost semiconductor layer NSL and lower than the level of the upper surface of the uppermost sacrificial layer 210.

In some embodiments, after the etch-back process, the upper surface of the insulating wall liner D10 and the upper surface of the buried insulating layer D20 may be arranged coplanar with the upper surface of the uppermost semiconductor layer NSL.

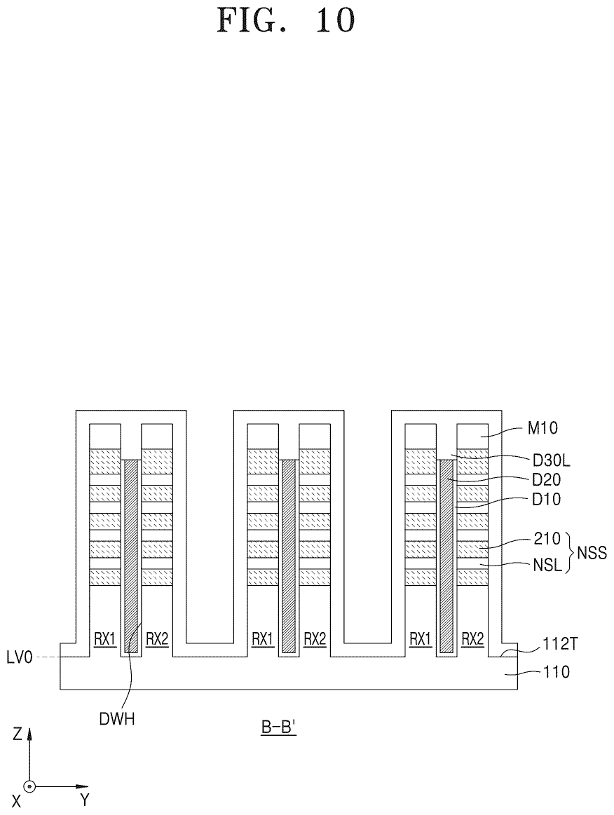

Referring to FIG. 10, a capping layer D30L may be formed to cover the semiconductor layer stack NSS. The capping layer D30L may be arranged to cover the upper surface of the insulating wall liner D10 and the buried insulating layer D20 on the upper portion of the insulating wall opening DWH. In embodiments, the capping layer D30L may include at least one of silicon nitride, silicon oxide, or silicon oxynitride.

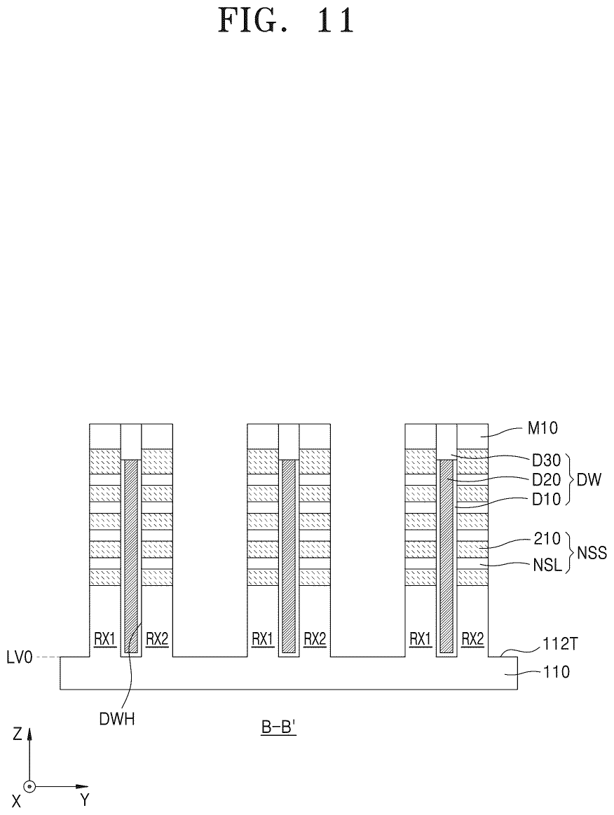

Referring to FIG. 11, an etch-back process may be performed on the capping layer D30L to re-expose the surface of the semiconductor layer stack NSS while leaving only a portion of the capping layer D30L on the upper portion of the insulating wall opening DWH.

In this case, a portion of the capping layer D30L remaining on the upper portion of the insulating wall opening DWH may be referred to as an insulating wall capping layer D30. The insulating wall liner D10, the buried insulating layer D20, and the insulating wall capping layer D30 may be arranged within the insulating wall opening DWH to form an integrated wall structure and may be collectively referred to as an insulating wall DW.

In embodiments, the interior of the insulating wall opening DWH may be filled with the insulating wall DW, and the device isolation trench 112T may not be filled.

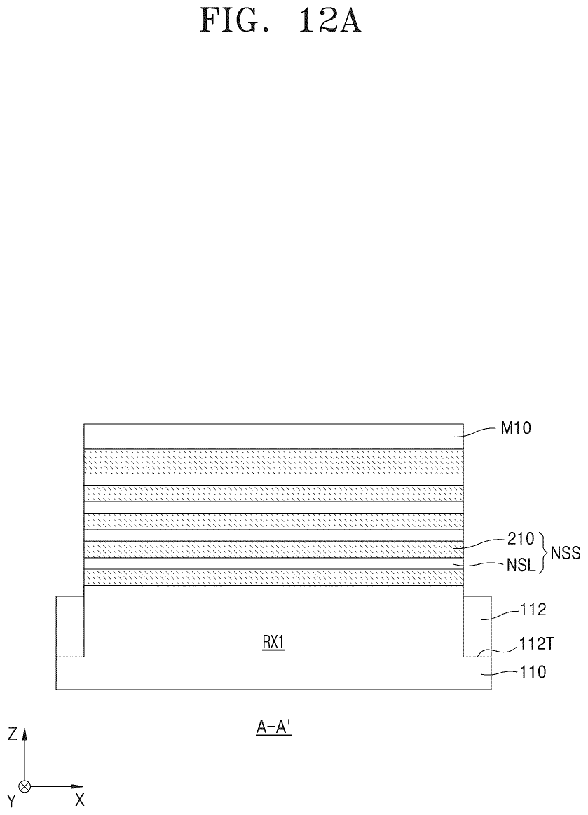

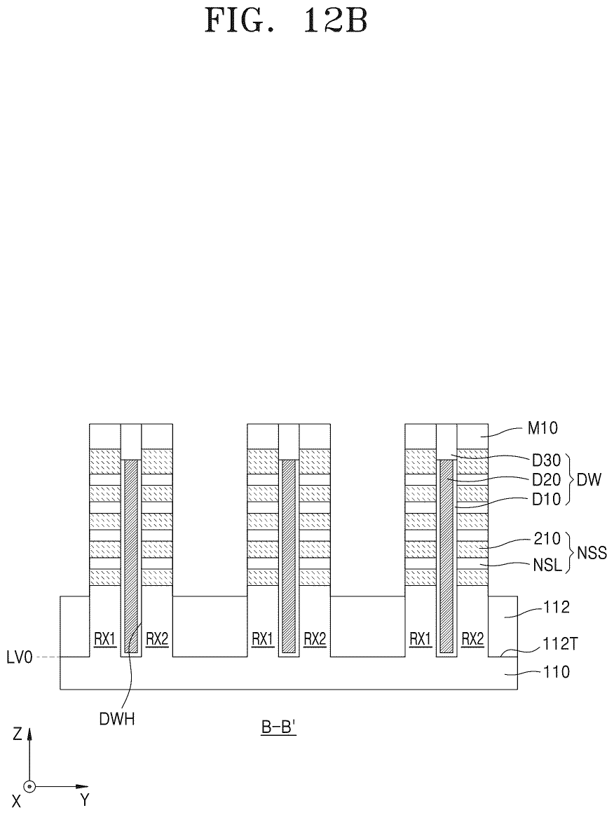

Referring to FIGS. 12A and 12B, a device isolation layer 112 may be formed within the device isolation trench 112T.

In some embodiments, an insulating layer may be formed on an inner wall of the device isolation trench 112T and on the semiconductor layer stack NSS, and the upper portion of the insulating layer may be etched back to leave the device isolation layer 112 on the inner wall of the device isolation trench 112T. In the process of forming the insulating layer on the semiconductor layer stack NSS and/or the process of etching back the insulating layer, the upper surface of the insulating wall liner D10 may be covered by the insulating wall capping layer D30 and thus may not be exposed to the outside or to an etching atmosphere. Accordingly, the insulating wall liner D10 may be prevented from being damaged or lost in the process of forming the insulating layer and/or the process of etching back the insulating layer.

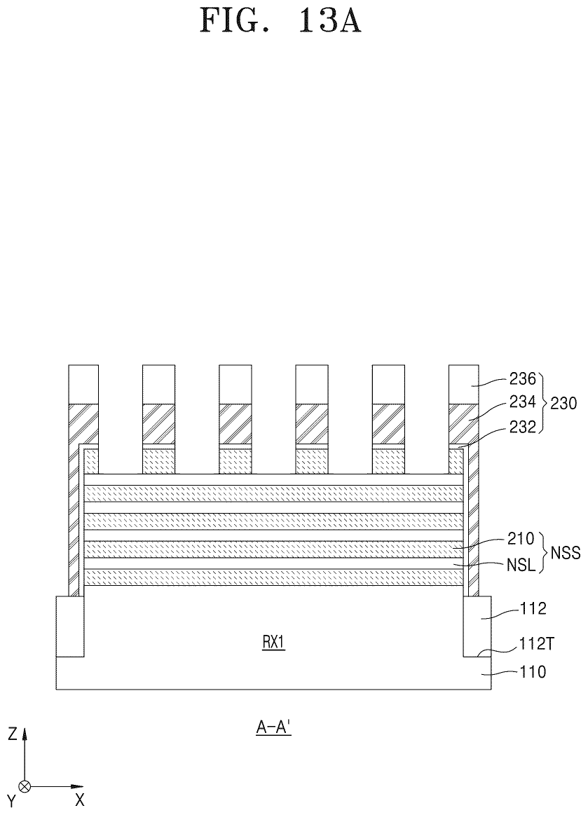

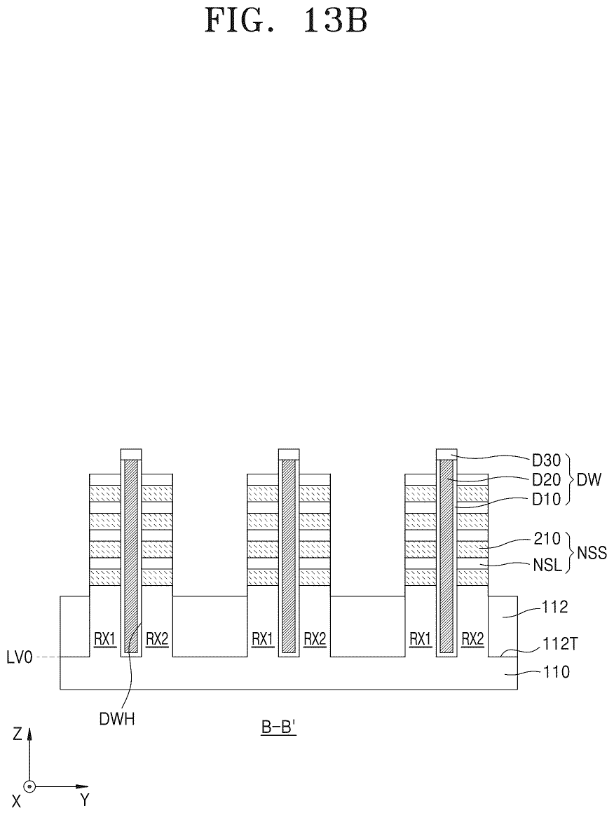

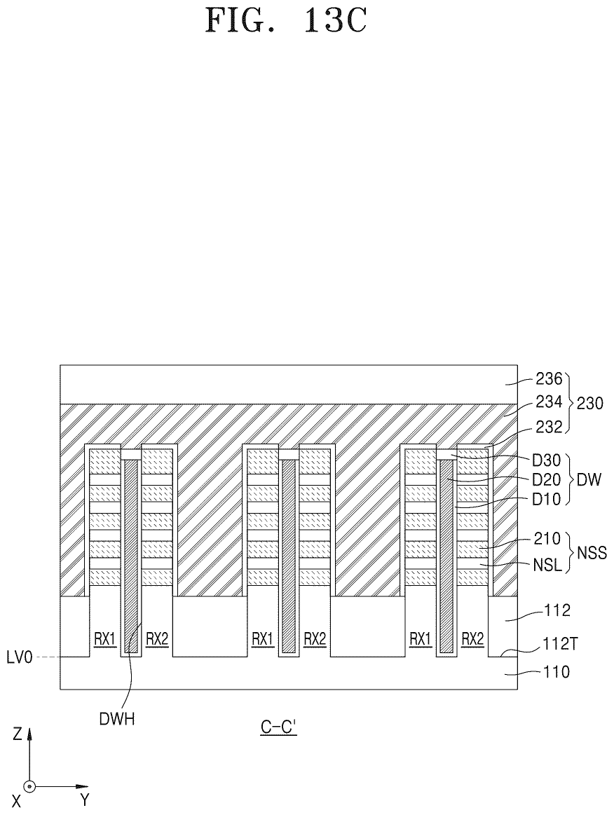

Referring to FIGS. 13A to 13C, the mask pattern M10 (see FIG. 12A) may be removed.

During or after the removal of the mask pattern M10, a portion of the upper portion of the insulating wall capping layer D30 may be removed. As a result, the upper surface of the insulating wall capping layer D30 may be arranged at the same level as the upper surface of the semiconductor layer stack NSS (or the upper surface of the uppermost sacrificial layer 210).

Thereafter, a sacrificial gate structure 230 covering the semiconductor layer stack NSS on the substrate 110 and extending in the second horizontal direction Y may be formed. The sacrificial gate structure 230 may include a sacrificial gate insulating layer 232, a sacrificial gate electrode 234, and a sacrificial capping layer 236. In embodiments, the sacrificial gate electrode 234 may be formed using polysilicon. The sacrificial capping layer 236 may be formed using silicon nitride.

In embodiments, the sacrificial gate insulating layer 232 may include silicon oxide obtained by performing a thermal oxidation process on the surface of the semiconductor layer stack NSS. In other embodiments, the sacrificial gate insulating layer 232 may include silicon oxide formed by performing a CVD process or an ALD process on the surface of the semiconductor layer stack NSS.

In embodiments, after forming the sacrificial gate structure 230 on the semiconductor layer stack NSS, the sacrificial gate structure 230 may be used as an etching mask to remove the uppermost sacrificial layer 210 and expose the upper surface of the uppermost semiconductor layer NSL.

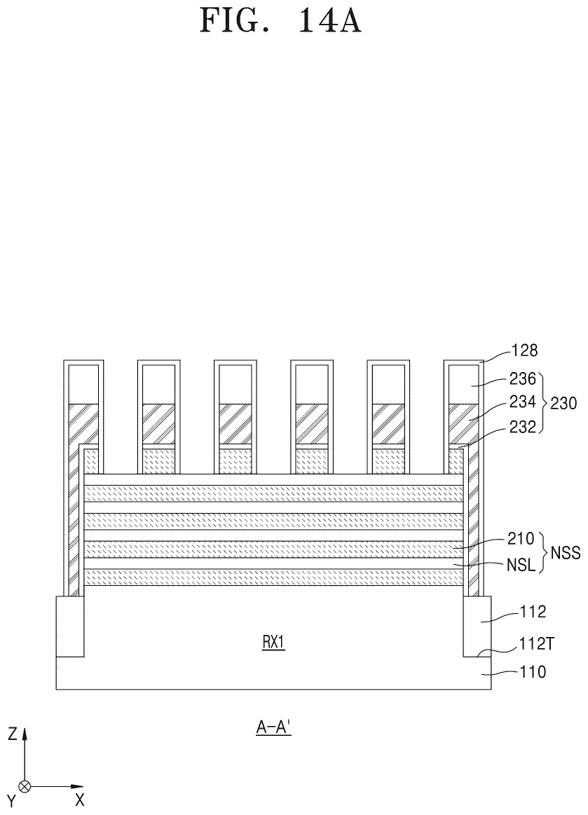

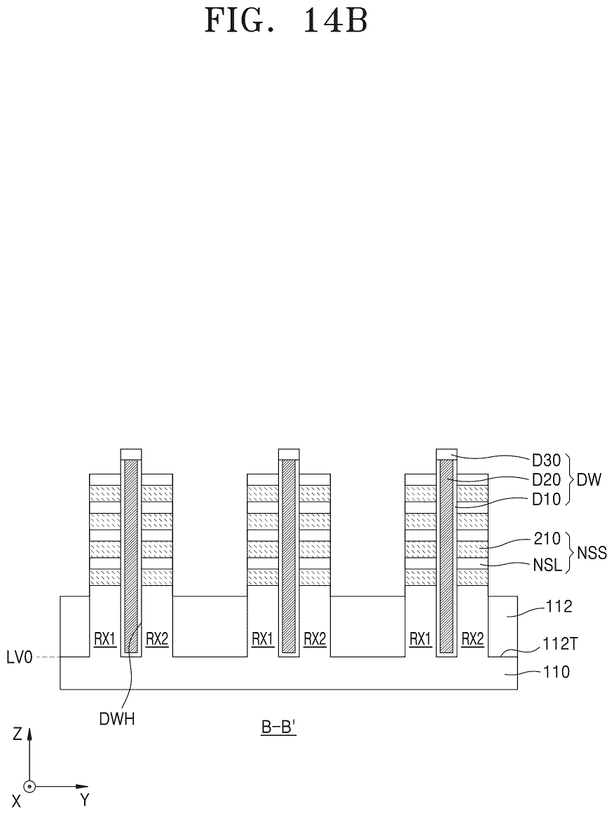

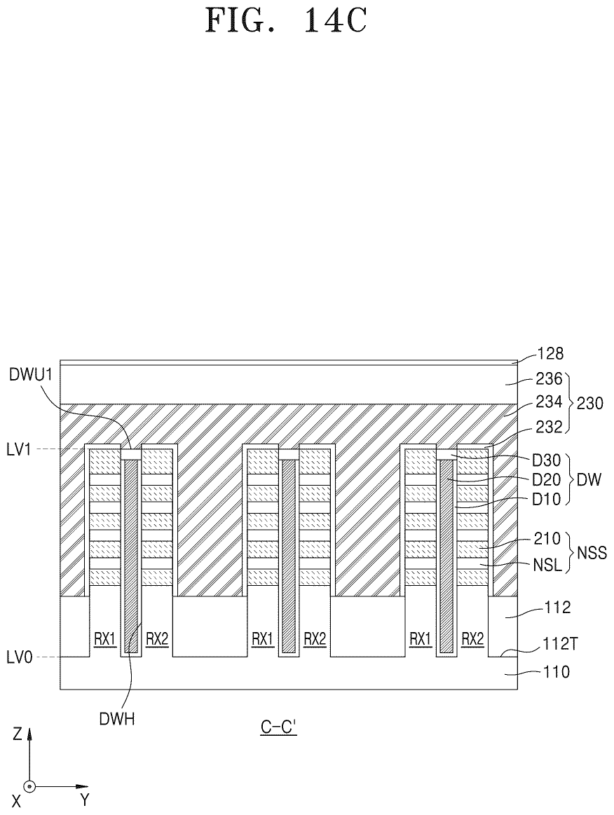

Referring to FIGS. 14A to 14C, a spacer 128 may be formed on the upper surface and sidewall of the sacrificial gate structure 230. The spacer 128 may be formed using silicon nitride.

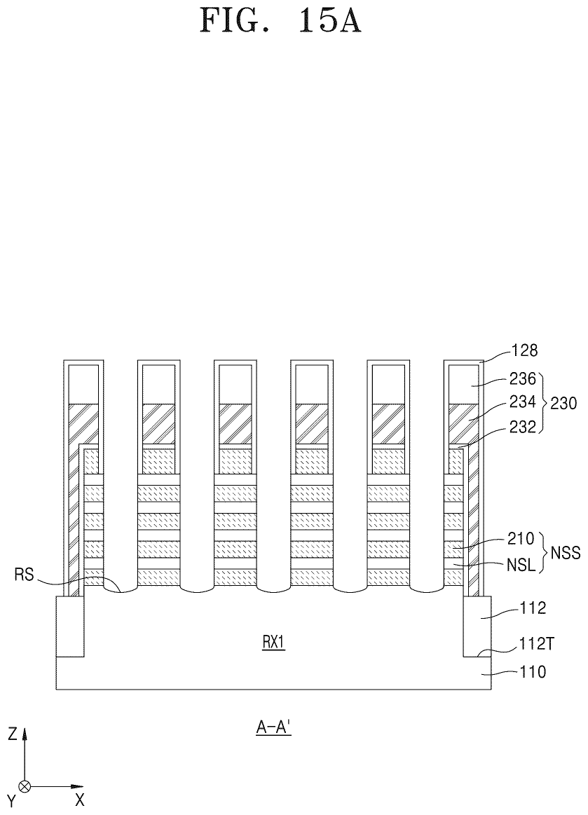

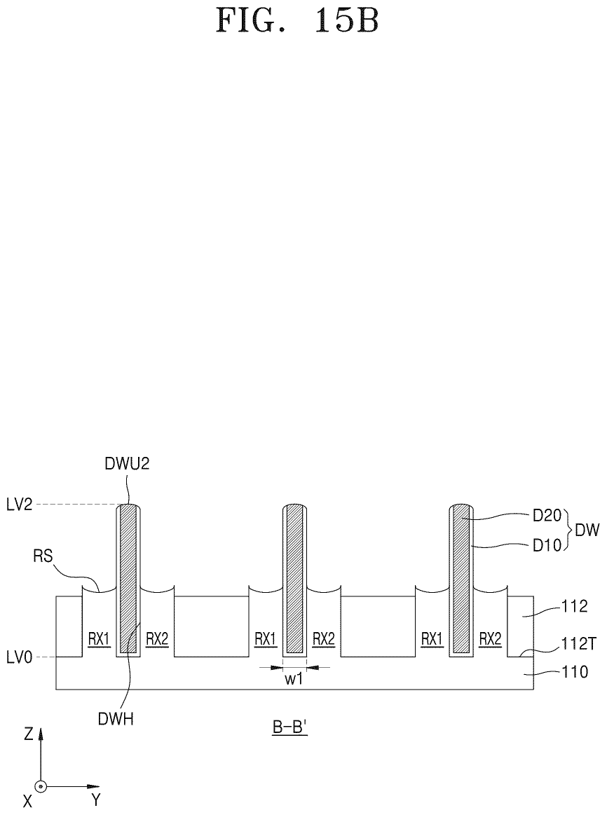

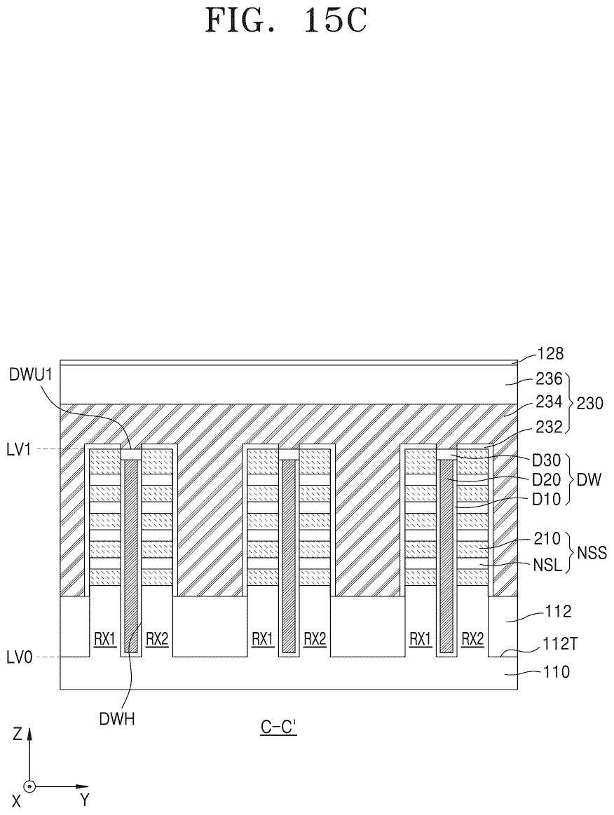

Referring to FIGS. 15A to 15C, a recess process may be performed on a portion of the insulating wall DW that is arranged at a higher vertical level than the uppermost semiconductor layer NSL and protrudes upwardly from the uppermost semiconductor layer NSL, thereby reducing the height of the upper portion of the insulating wall DW.

In embodiments, during the recess process, the insulating wall capping layer D30 on the upper portion of the insulating wall DW may be removed, resulting in a reduction in the height of the upper surface of the insulating wall DW. A portion of the insulating wall DW of which the height is reduced as a result of the recess process is referred to as a second portion DWU2, and a portion of the insulating wall DW that is covered by the sacrificial gate structure 230 and is not subjected to a recess process and of which the height is maintained the same is referred to as a first portion DWU1. The upper surface of the second portion DWU2 may be arranged at a level lower than the upper surface of the first portion DWU1. For example, the upper surface of the first portion DWU1 covered by the sacrificial gate structure 230 may be arranged at a first vertical level LV1, and the upper surface of the second portion DWU2 may be arranged at a second vertical level LV2 that is lower than the first vertical level LV1.

Thereafter, a portion of the semiconductor layer stack NSS between the sacrificial gate structures 230 may be removed to form a recess RS. The recess RS may extend into portions of the first active region RX1 and the second active region RX2.

In the process of removing a portion of the semiconductor layer stack NSS, a portion of the upper portion of the insulating wall DW, for example, the upper portion of the second portion DWU2, may be removed. As a result of this process, the second portion DWU2 may include a rounded upper surface, and the upper surface of the second portion DWU2 may be at a level lower than the upper surface of the first portion DWU1. For example, the upper surface of the first portion DWU1 covered by the sacrificial gate structure 230 may be at the first vertical level LV1, and the upper surface of the second portion DWU2 may be at the second vertical level LV2 that is lower than the first vertical level LV1.

According to embodiments, because the second portion DWU2 of the insulating wall DW has a relatively small height in the process of removing a portion of the semiconductor layer stack NSS, the process of removing a portion of the semiconductor layer stack NSS within the recess RS may be precisely controlled.

Referring to FIGS. 16A to 16C, a source/drain region SD may be formed on the upper surface of the substrate 110 exposed on both sides of the sacrificial gate structure 230 to fill the inside of the recess RS.

In embodiments, the source/drain region SD may be formed by epitaxially growing a semiconductor material from the sacrificial layer 210, the semiconductor layer NSL, and the surface of the substrate 110. The source/drain region SD may include at least one of an epitaxially grown Si layer, an epitaxially grown SiC layer, an epitaxially grown SiGe layer, and an epitaxially grown SiP layer.

In embodiments, a source/drain region SD (herein, referred to as a first source/drain region SD1) arranged on the first active region RX1 and a source/drain region SD (herein, referred to as a second source/drain region SD2) arranged on the second active region RX2 may be apart from each other in the second horizontal direction Y with the second portion DWU2 of the insulating wall DW therebetween. The upper portions of the first source/drain region SD1 and the second source/drain region SD2 may be apart from each other by a relatively small separation distance w2 at a higher vertical level than the upper surface of the second portion DWU2 of the insulating wall DW.

In embodiments, the source/drain region SD may include a lower sidewall SD_L in contact with the second portion DWU2 of the insulating wall DW, and an upper sidewall SD_U that is arranged at a vertical level higher than the lower sidewall SD_L and not in contact with the second portion DWU2 of the insulating wall DW.

In some embodiments, the upper sidewall SD_U of the source/drain region SD may protrude outwardly with respect to the lower sidewall SD_L of the source/drain region SD. For example, the upper sidewall SD_U of the source/drain region SD may be apart from the lower sidewall SD_L of the source/drain region SD by a first distance d1 in the second horizontal direction Y. In embodiments, the first distance d1 may be in a range of about 0.1 nanometers to about 5 nanometers.

In some embodiments, the insulating wall DW may have a first width w1 in the second horizontal direction Y, and the first width w1 may be in a range of about 15 nanometers to about 25 nanometers. Because the upper sidewall SD_U of the source/drain region SD protrudes outwardly (or grows laterally) by the first distance d1, which is relatively small, with respect to the lower sidewall SD_L, the first source/drain region SD1 and the second source/drain region SD2 may not merge with each other in an epitaxial growth process.

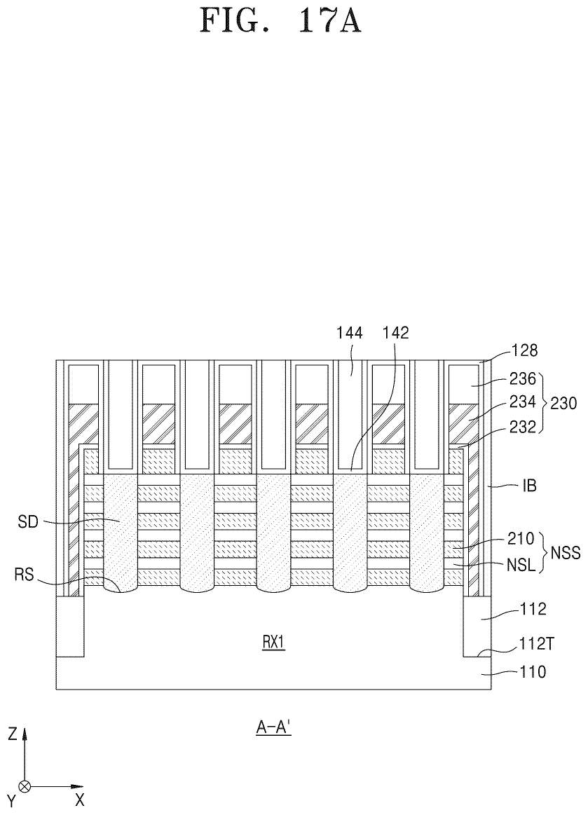

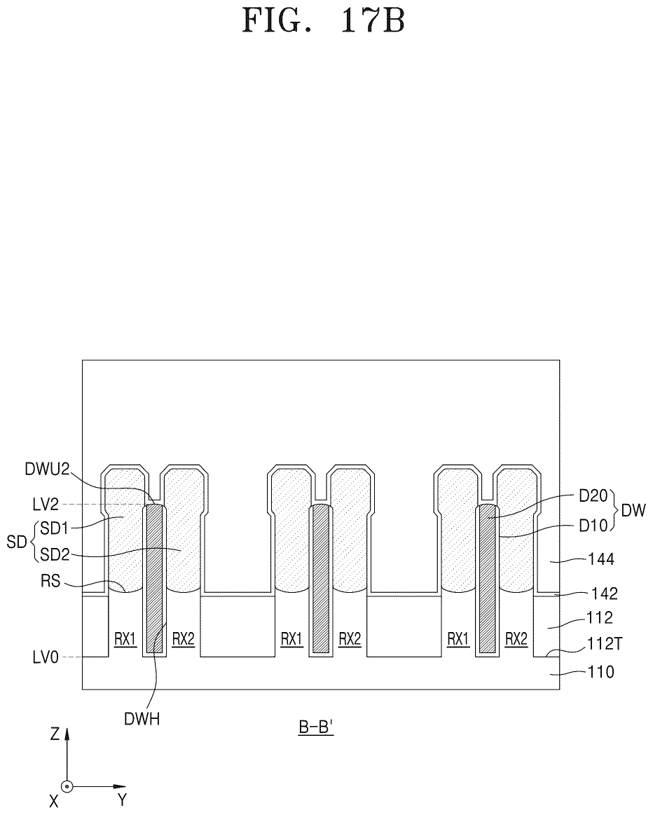

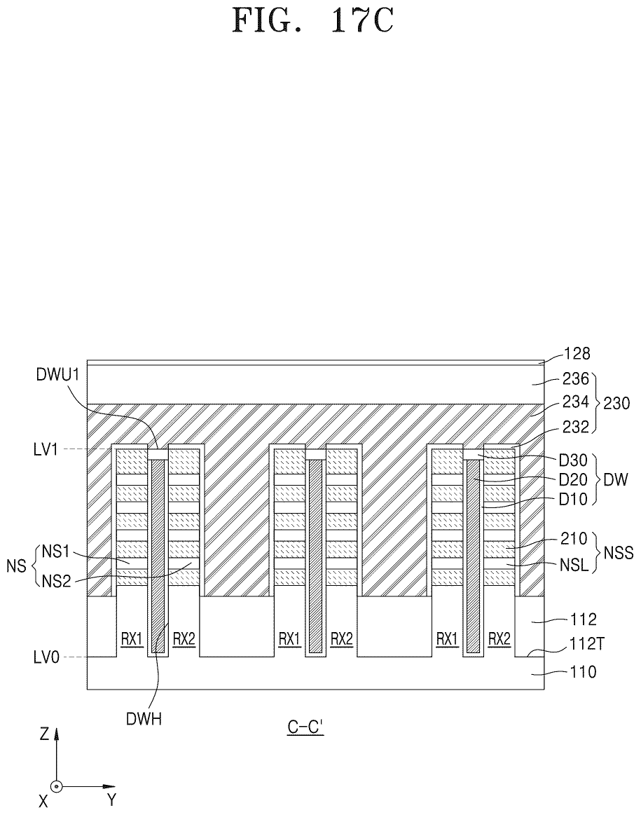

Referring to FIGS. 17A to 17C, an etch stop layer 142 covering the source/drain region SD, and an inter-gate insulating layer 144 may be formed.

The etch stop layer 142 may conformally cover the first source/drain region SD1 and the second source/drain region SD2, and a portion of the etch stop layer 142 may be arranged on the upper surface of the second portion DWU2 of the insulating wall DW.

In the process for forming the inter-gate insulating layer 144 or after forming the inter-gate insulating layer 144, an insulating structure IB covering the end of the semiconductor layer stack NSS in the first horizontal direction X may be formed.

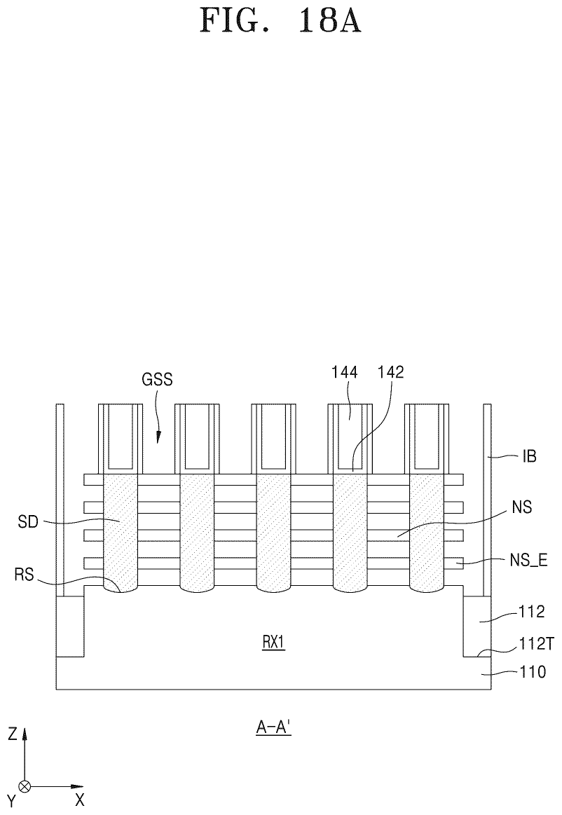

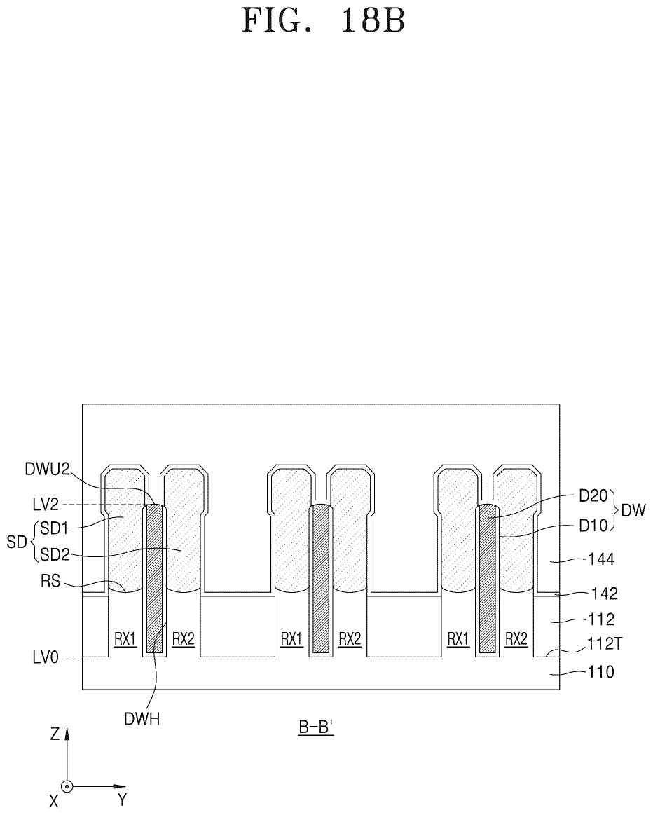

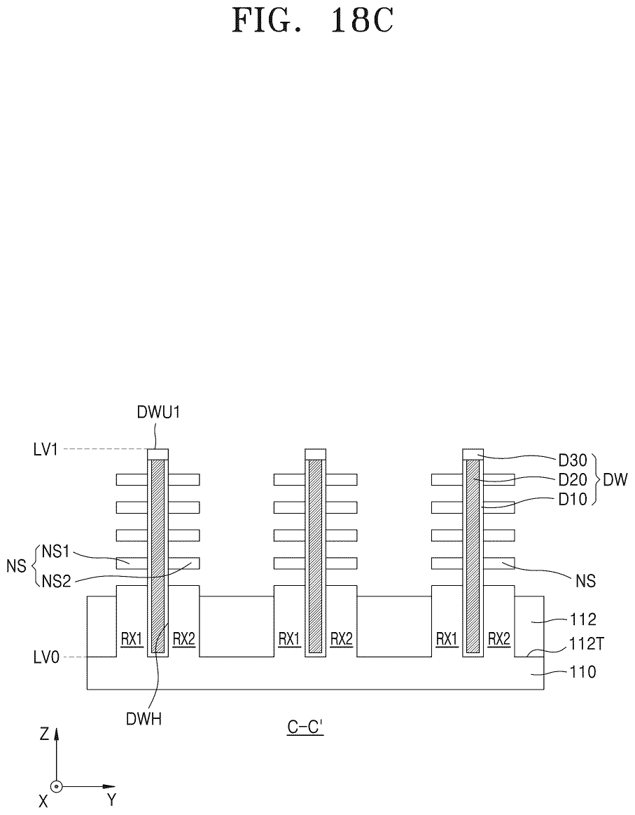

Referring to FIGS. 18A to 18C, the sacrificial gate structure 230 may be removed and a gate space GSS may be formed. The sacrificial layer 210 exposed to the gate space GSS may be removed to expose the upper surface and bottom surface of the semiconductor layer NSL. The process of removing the sacrificial layer 210 may be a wet etching process utilizing an etching selectivity between the sacrificial layer 210 and the semiconductor layer NSL.

In embodiments, the semiconductor layer NSL exposed after the sacrificial layer 210 is removed may be referred to as a semiconductor pattern NS. The semiconductor layer NSL included in the end of the semiconductor layer stack NSS in the first horizontal direction X may be referred to as an edge semiconductor pattern NS_E. The edge semiconductor pattern NS_E may be arranged adjacent to the insulating structure IB.

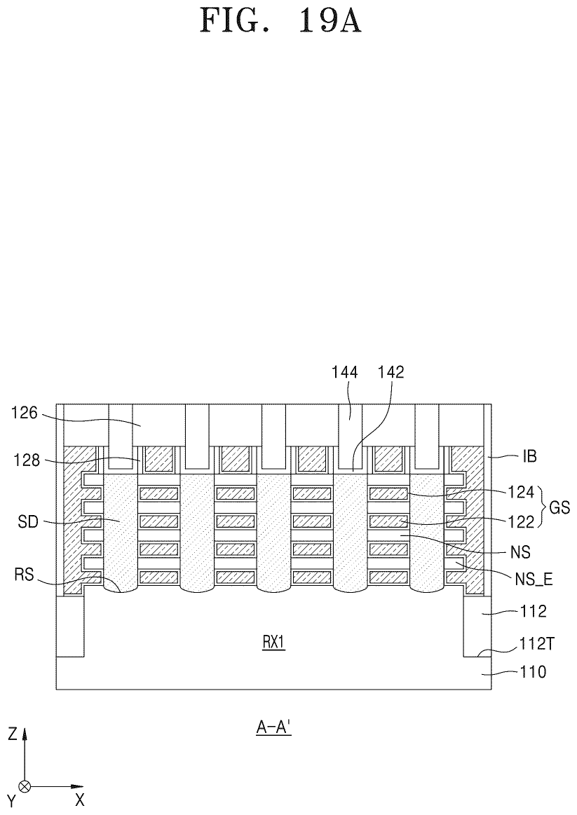

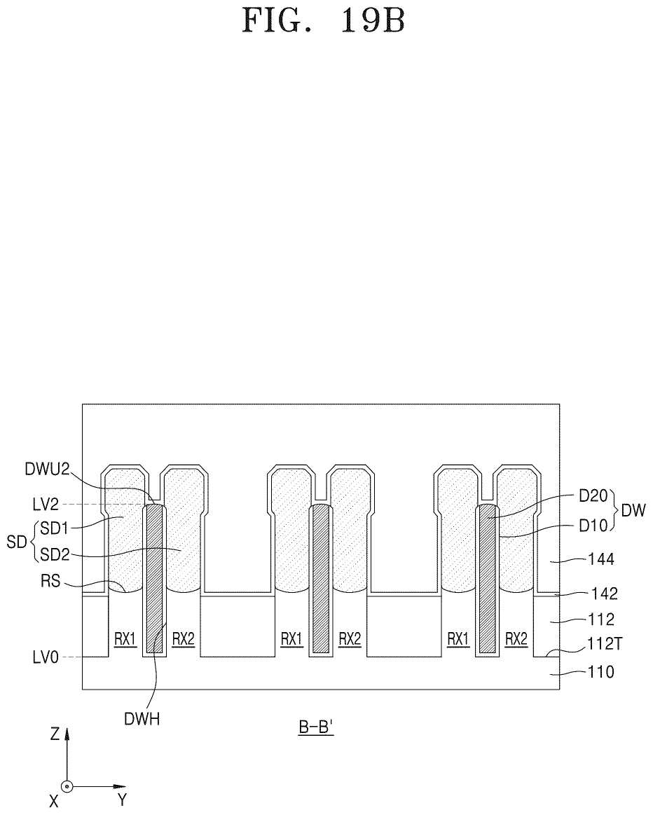

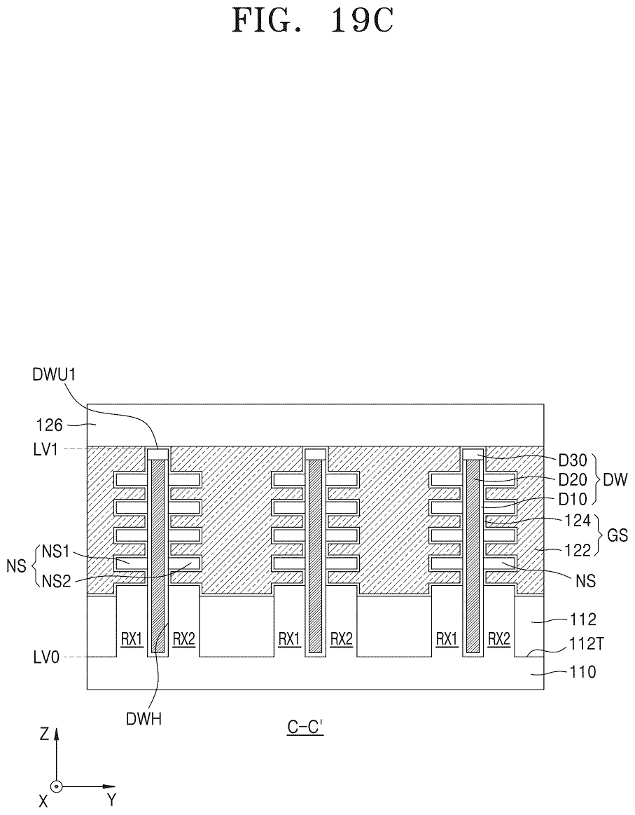

Referring to FIGS. 19A to 19C, a gate insulating layer 124 and a gate electrode 122 may be formed in a space (i.e., the gate space GSS illustrated in FIG. 18A) where the sacrificial gate structure 230 has been removed. The gate electrode 122, the gate insulating layer 124, and a capping layer 126 may be collectively referred to as a gate structure GS and may surround a plurality of semiconductor patterns NS spaced apart from each other in the vertical direction Z and extend in the second horizontal direction Y.

As the spacer 128 is arranged on the uppermost semiconductor pattern NS, a portion of the gate electrode 122 arranged at a higher level than the uppermost semiconductor pattern NS may have a smaller width (e.g., a width in the first horizontal direction X) than a portion of the gate electrode 122 arranged between two adjacent semiconductor patterns NS.

Thereafter, the capping layer 126 may be formed on the upper surface of the gate electrode 122. In embodiments, the capping layer 126 may be arranged to contact a sidewall of the inter-gate insulating layer 144.

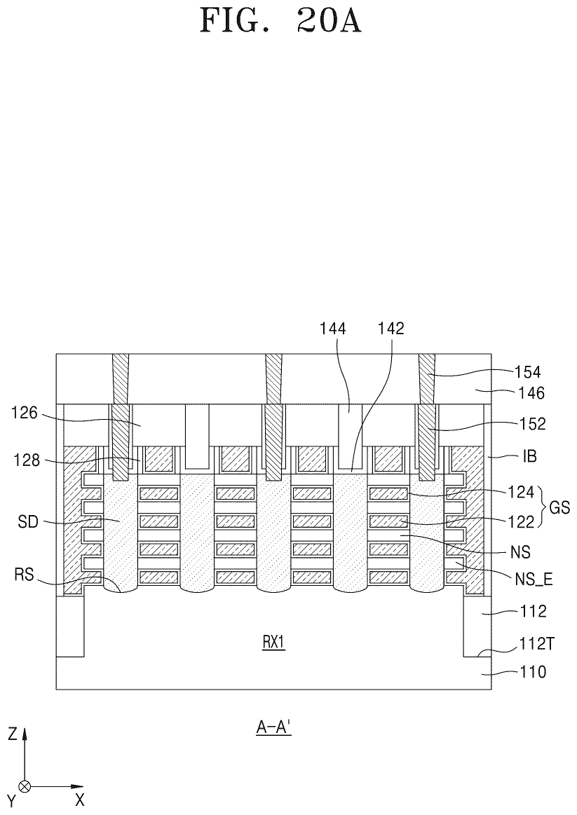

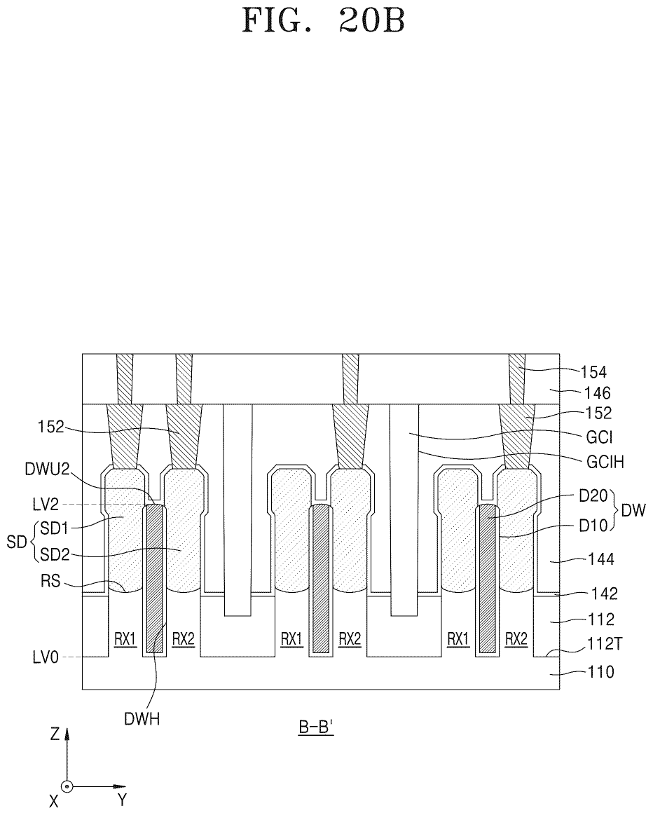

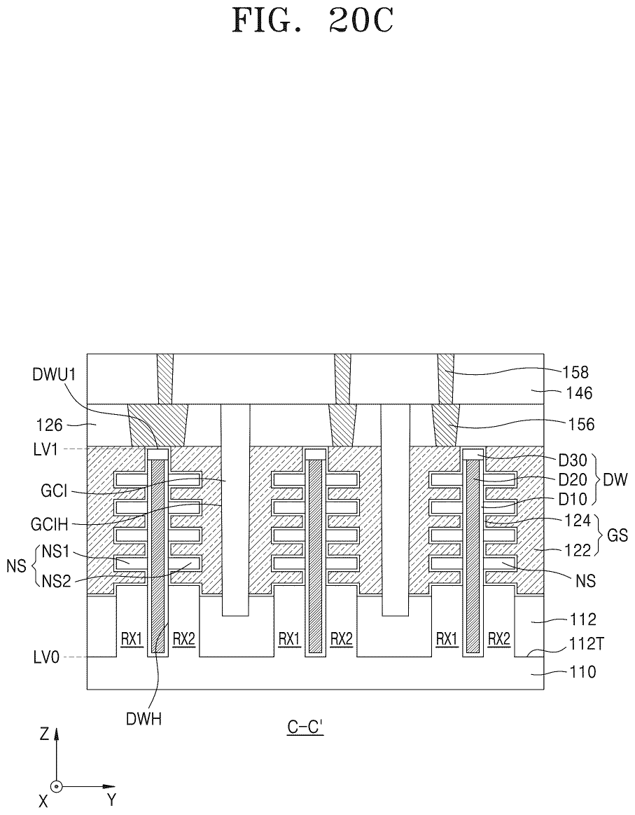

Referring to FIGS. 20A to 20C, a portion of a gate structure GS may be removed to form a gate cut region GCIH, and an insulating material may be used to form a gate cut insulating layer GCI inside the gate cut region GCIH. The bottom of the gate cut insulating layer GCI may protrude toward the device isolation layer 112 and may contact the device isolation layer 112.

A first contact 152 that is electrically connected to the source/drain region SD by passing through the gate inter-insulating layer 144 and the etch stop layer 142 may be formed, and a second contact 156 that is electrically connected to the gate electrode 122 by passing through the capping layer 126 may be formed. Thereafter, an upper insulating layer 146 is formed on the gate structure GS, the gate cut insulating layer GCI, and the gate inter-insulating layer 144. A first via 154 that passes through the upper insulating layer 146 and is electrically connected to the first contact 152 may be formed, and a second via 158 that passes through the upper insulating layer 146 and is electrically connected to the second contact 156 may be formed.

Referring again to FIGS. 3A to 3C, a front wiring layer FSW, a front via FSV, and a front insulating layer FSI may be formed on the upper insulating layer 146. Accordingly, a front wiring structure FS may be completed.

Generally, in order to form an integrated circuit device having a forksheet structure in which a semiconductor pattern is arranged with an insulating wall therebetween, an insulating wall is first formed and then a semiconductor pattern is formed. However, in this case, residue from the semiconductor pattern may not be completely removed, thereby deteriorating the device performances. In contrast, a method of forming an insulating wall by etching between semiconductor patterns after forming the semiconductor patterns has been proposed, but in this method, the width deviations of the semiconductor patterns may increase due to the etching process, thereby deteriorating the device performances.

However, in the integrated circuit device 100 according to embodiments, the insulating wall DW including the insulating wall liner D10, the buried insulating layer D20, and the insulating wall capping layer D30 is formed, and a recess process is performed on the upper portion of the insulating wall DW to reduce the height of the insulating wall DW, and then the source/drain region SD may be grown. Since the insulating wall liner D10 includes a low-k dielectric material, a coupling effect may be prevented and threshold voltage control characteristics of the integrated circuit device 100 may be improved.

In addition, since the insulating wall capping layer D30 covers the upper surface of the insulating wall liner D10, loss or damage of the insulating wall DW, which may occur when the upper surface of the insulating wall liner D10 is exposed during a process of forming the device isolation layer 112 and/or an etch-back process, may be prevented. Therefore, the integrated circuit device 100 may have excellent electrical performance.

According to an integrated circuit device of the inventive concept, an insulating wall including an insulating wall liner, a buried insulating layer, and an insulating wall capping layer is formed, and a recess process is performed on the upper portion of the insulating wall to lower the height of the insulating wall, and then a source/drain region is grown. Because the insulating wall liner includes a low-k material, a coupling effect may be prevented and threshold voltage control characteristics of the integrated circuit device may be improved. In addition, because the insulating wall capping layer covers the upper surface of the insulating wall liner, loss or damage of the insulating wall that may occur when the upper surface of the insulating wall liner is exposed during a process of forming the device isolation layer may be prevented. Therefore, the integrated circuit device may have excellent electrical performance.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An integrated circuit device comprising:
at least one first semiconductor pattern extending in a first horizontal direction;
a first source/drain region connected to an end of the at least one first semiconductor pattern in the first horizontal direction;
at least one second semiconductor pattern extending in the first horizontal direction and spaced apart from the at least one first semiconductor pattern in a second horizontal direction;
a second source/drain region connected to an end of the at least one second semiconductor pattern in the first horizontal direction; and
an insulating wall in an insulating wall opening that extends in the first horizontal direction, between the at least one first semiconductor pattern and the at least one second semiconductor pattern and between the first source/drain region and the second source/drain region,
wherein the insulating wall comprises:
an insulating wall liner on an inner wall of the insulating wall opening;
a buried insulating layer on the insulating wall liner; and
an insulating wall capping layer on an upper surface of the insulating wall liner and an upper surface of the buried insulating layer in the insulating wall opening.

2. The integrated circuit device of claim 1, wherein the insulating wall comprises:
a first portion between the at least one first semiconductor pattern and the at least one second semiconductor pattern; and
a second portion between the first source/drain region and the second source/drain region,
wherein an upper surface of the second portion is at a level lower than an upper surface of the first portion in a vertical direction.

3. The integrated circuit device of claim 2, wherein the upper surface of the second portion of the insulating wall is at the level lower than an upper surface of the first source/drain region and an upper surface of the second source/drain region in the vertical direction.

4. The integrated circuit device of claim 2, wherein an upper portion of the first source/drain region is spaced apart from an upper portion of the second source/drain region in the second horizontal direction.

5. The integrated circuit device of claim 2, wherein the insulating wall capping layer is in the first portion of the insulating wall, and the insulating wall capping layer is outside the second portion of the insulating wall.

6. The integrated circuit device of claim 2, wherein ends of the at least one first semiconductor pattern in the second horizontal direction are in contact with a first sidewall of the insulating wall, and ends of the at least one second semiconductor pattern in the second horizontal direction are in contact with a second sidewall of the insulating wall opposite to the first sidewall.

7. The integrated circuit device of claim 6, wherein the ends of the at least one first semiconductor pattern in the second horizontal direction and the ends of the at least one second semiconductor pattern in the second horizontal direction are in contact with the insulating wall liner.

8. The integrated circuit device of claim 2, further comprising:
a gate electrode surrounding the at least one first semiconductor pattern and the at least one second semiconductor pattern and extending in the second horizontal direction; and
a gate insulating layer between the at least one first semiconductor pattern and the gate electrode and between the at least one second semiconductor pattern and the gate electrode,
wherein the gate insulating layer extends onto the upper surface of the first portion of the insulating wall.

9. The integrated circuit device of claim 8, wherein the gate insulating layer is on an upper surface of the insulating wall capping layer in the first portion of the insulating wall.

10. The integrated circuit device of claim 2, wherein the insulating wall has a width of 15 nanometers to 25 nanometers in the second horizontal direction.

11. The integrated circuit device of claim 2, wherein the first source/drain region comprises:
a lower sidewall in contact with the second portion of the insulating wall; and
an upper sidewall at the level higher than the lower sidewall in the vertical direction and spaced apart from the second portion of the insulating wall,
wherein the upper sidewall protrudes outwardly with respect to the lower sidewall, and the upper sidewall is spaced apart from the lower sidewall by a first distance of 0.1 nanometers to 5 nanometers in the second horizontal direction.

12. The integrated circuit device of claim 2, wherein the upper surface of the insulating wall liner included in the first portion of the insulating wall is at the level higher than an upper surface of the at least one first semiconductor pattern in the vertical direction, and the upper surface of the insulating wall liner included in the first portion of the insulating wall is at the level lower than an upper surface of the insulating wall capping layer included in the first portion of the insulating wall in the vertical direction.

13. An integrated circuit device comprising:
a first active region and a second active region extending in a first horizontal direction;
an insulating wall extending in the first horizontal direction between the first active region and the second active region;
at least one first semiconductor pattern on the first active region and extending in the first horizontal direction;
a first source/drain region on the first active region and connected to the at least one first semiconductor pattern;
at least one second semiconductor pattern that is on the second active region and extends in the first horizontal direction; and
a second source/drain region on the second active region and connected to the at least one second semiconductor pattern,
wherein the insulating wall comprises:
a buried insulating layer extending in the first horizontal direction between the at least one first semiconductor pattern and the at least one second semiconductor pattern and between the first source/drain region and the second source/drain region;
an insulating wall liner on sidewalls of the buried insulating layer; and
an insulating wall capping layer on an upper surface of the insulating wall liner and an upper surface of the buried insulating layer.

14. The integrated circuit device of claim 13, wherein the insulating wall liner is in contact with the at least one first semiconductor pattern, the at least one second semiconductor pattern, the first source/drain region, and the second source/drain region.

15. The integrated circuit device of claim 13, wherein the insulating wall capping layer is between the at least one first semiconductor pattern and the at least one second semiconductor pattern, and is spaced apart from a region between the first source/drain region and the second source/drain region.

16. The integrated circuit device of claim 13, wherein the insulating wall comprises:
a first portion between the at least one first semiconductor pattern and the at least one second semiconductor pattern; and
a second portion between the first source/drain region and the second source/drain region,
wherein an upper surface of the second portion is at a level lower than an upper surface of the first portion in a vertical direction.

17. The integrated circuit device of claim 16, wherein the upper surface of the second portion of the insulating wall is at the level lower than an upper surface of the first source/drain region and an upper surface of the second source/drain region in the vertical direction.

18. The integrated circuit device of claim 16, wherein each of the first source/drain region and the second source/drain region comprises:
a lower sidewall in contact with the second portion of the insulating wall; and
an upper sidewall at the level higher than the lower sidewall in the vertical direction, and spaced apart from the second portion of the insulating wall,
wherein the upper sidewall protrudes outwardly with respect to the lower sidewall, and the upper sidewall is spaced apart from the lower sidewall by a first distance of 0.1 nanometers to 5 nanometers in a second horizontal direction intersecting the first horizontal direction.

19. The integrated circuit device of claim 18, wherein the upper sidewall of the first source/drain region is spaced apart from the upper sidewall of the second source/drain region in the second horizontal direction.

20. An integrated circuit device comprising:
a substrate comprising a first active region and a second active region;
at least one first semiconductor pattern and at least one second semiconductor pattern provided on the first active region and the second active region, respectively;
a first source/drain region and a second source/drain region that are on the first active region and the second active region, respectively, and are connected to the at least one first semiconductor pattern and the at least one second semiconductor pattern, respectively; and
an insulating wall between the first active region and the second active region, and between the at least one first semiconductor pattern and the at least one second semiconductor pattern;
wherein the insulating wall comprises:
a buried insulating layer;
an insulating wall liner on sidewalls of the buried insulating layer; and
an insulating wall capping layer on an upper surface of the insulating wall liner and an upper surface of the buried insulating layer.
